(19) United States
(12) Patent Application Publication
(10) Pub. No.: US 2023/0359017 A1
(43) Pub. Date: Nov. 9, 2023

(54) Systems and Methods for Coherent Beam Combining

(71) Applicant: ELBIT SYSTEMS ELECTRO-OPTICS - ELOP LTD., Rehovot (IL)

(72) Inventors: Zeev SCHIFFER, Rehovot (IL); Andrey NAZAROV, Rehovot (IL); Daniel LEVY, Rehovot (IL)

(21) Appl. No.: 18/341,785

(22) Filed: Jun. 27, 2023

Related U.S. Application Data
(63) Continuation-in-part of application No. 18/147,715, filed on Dec. 29, 2022, now Pat. No. 11,735,886.
Application No. 18/147,715 is a continuation of application No. PCT/IL2021/050730, filed on Jun. 16, 2021.

(30) Foreign Application Priority Data
Jul. 1, 2020 (IL) 275783

(51) Int. Cl. G02B 26/06; G02B 27/10

(52) U.S. Cl. CPC G02B 26/06; G02B 27/106

(57) ABSTRACT

Multi-Channels coherent beam combining (CBC) using a mechanism for phase and/or polarization locking that uses a reference optical beam and an array of optical detectors each detector being configured and located to detect overall intensity of an optical interference signal caused by interfering of the reference beam and a beam of the respective channel, where the fast intensity per-channel detection allows simultaneous and quick phase/polarization locking of all channels for improving beam combining system performances.

The present disclosure relates in general to systems and methods for coherent beam combining incorporating a phase locking and/or polarization locking mechanism.

### BACKGROUND

Near diffraction-limit High power lasers, such as amplification fiber lasers (fiber amplifiers), have a variety of scientific and industrial implementations and enable achieving high power output optical signals having excellent beam quality. However, for a single fiber laser, maintaining its near diffraction limit beam quality may be limited, mainly due to three physical phenomena: Stimulated Brillouin Scattering, Stimulated Raman Scattering and modal thermal instability. To overcome these limitations, techniques for combining multiple optical beams are used, which combine multiple optical beams emanating from multiple fiber lasers into a single combined optical beam.

The techniques and system layouts used for combining multiple optical beams depend, inter alia, on the spectral coherency of these optical beams, where combination of spectrally coherent optical beams, known as coherent beam combining (CBC), may be carried out by using a phased array (also known as “side-by-side CBC) such as an array of collimators, each collimating a separate optical beam. Other techniques for CBC involve using one or more diffraction grating elements (also known as “field aperture techniques”).

### SUMMARY

Aspects of disclosed embodiments pertain to a method for locking phases of an array of channel optical beams propagated through channels of a coherent beam combining (CBC) system, the method comprising at least:
(a) generating a reference optical beam;
(b) generating an array of sample optical beams, sampled from the array of channel optical beams, and causing optical interference between each part of the reference optical beam and a corresponding sample optical beam, generating thereby an array of corresponding interference optical signals;
(c) for each channel “I” and channel optical beam's phase testing iteration “ι”, for testing channel beam phase φ_{Iι}:

sequentially changing a phase difference Δφ_{Iι} between the phase of the channel optical beam or part thereof and the corresponding part of the reference optical beam, by a discrete set of phase shifts δφₖ, where k=1 . . . m, “m” being an integer number larger than 1, defining a discrete sequence of “m” shifting-modes;
measuring updated power parameter value P_{Iιk} of the interference optical signal for each phase shift δφₖ, resulting in a corresponding set 1 to m power parameter values, each associated with a different phase shift δφₖ, for the respective channel “I” and respective “ι” phase testing iteration, where the power parameter is associated with an intensity of the corresponding interference signal of the corresponding channel “I” and phase testing iteration “ι”;

determining an updated value of a modes-parameter R_{ιI}, mathematically related to all “m” detected power parameter values P_{Iιk} for the respective channel “I” and the respective phase testing iteration “ι”; and
(d) controlling phase locking of phase of each channel optical beam according to the phase of the corresponding channel optical beam that is associated with the value of the modes-parameter of the corresponding channel that complies with at least one locking criterion.

According to some embodiments, the changing of the phase difference between each channel optical beam and the reference optical beam may be carried out by one or more of:
(i) phase-modulating the reference optical beam by using a phase modulation device configured to modulate the entire reference optical beam, according to a discrete sequence of phase shifts δφₖ;
(ii) phase shifting the phase of each channel optical beam and/or its corresponding sample optical beam, using a phase shifter (PS) of the respective channel, by a discrete sequence of phase shifts δφₖ; and/or
(iii) phase shifting each portion of the reference optical beam separately, by a discrete sequence of phase shifts δφₖ, using an array of phase modulators (PMs) located such that each PM receives therethrough and phase-modulates a different portion of the reference optical beam directed to interfere with a corresponding sample optical beam.

According to some embodiments, the at least one criterion according to which the phase of each channel optical beam is controllably locked may be adjustable based on a currently desired spatial phase distribution of a combined optical beam outputted from the CBC system, for example, by controlling desired phase distribution of the combined optical beam by setting a different locking criterion to each channel, for causing intentional specific phase-differences between the channel optical beams, for enabling a desired phased-array beam steering of the combined optical beam.

According to some embodiments, the at least one locking criterion may include at least one of:
an extremum value of the modes-parameter, such that the phase of the channel optical beam is locked to the phase φ_{Iι} that yielded the minimum or maximum modes-parameter Ru value or an absolute value thereof |R_{ιI}|, between all modes-parameter values determined for all phases of the channel optical beam being tested in each phase locking session; and/or
a minimum value of an absolute distance D between the modes-parameter Ru and a predefined desired modes-parameter R_{d}: minimum of: D_{ιI}=|R_{d}−R_{ιI}∥, between all modes-parameter values determined for all phases of the channel optical beam being tested in each phase-locking session.

According to some embodiments, for each channel “I”, the overall number of testing iterations in each phase-locking session may be limited to a testing timeframe or to a predefined limiting number of testing iterations. For example, the phase-locking method steps may be performable in an ongoing and/or repeated manner such that phase-locking sessions for each channel are repeatedly performed during operation of the CBC system.

According to some embodiments, the overall timeframe for each phase testing iteration may be limited to a predefined testing timeframe ΔTt that corresponds to an estimated timespan ΔTₑ that is associated with an estimated timespan of a phase shifting sequence Δtₘ for measuring all “m” different phase shifting-modes for shifting the phase difference between the reference optical beam and the corresponding sample optical beam for the particular channel “I”, to enable detecting all power parameter values of all “m” shifting-modes.

According to some embodiments, the number of shifting-modes may be m=2 such that in the first shifting-mode, k=1, the phase difference between the phase of the reference and channel optical beam may be shifted by δφ₁=0 and in the second shifting-mode, k=2, the phase difference may be shifted by δφ₂=π/2.

According to some embodiments, the modes-parameter R_{ιI} of channel “I” and testing iteration “ι” is mathematically proportional or equal to

Δ=\sqrt{(Io₁−I₁)²+(Io₂−I₂)²}, where:

I₀₁ and I₀₂ are predefined constants of desired intensity values of the interference optical signal, respectively, for the first and second shifting-modes: k=1 and k=2;

I₁ is an updated intensity value of the specific channel “I” and specific iteration “ι” for the first shifting-mode k=1, which is proportional to its corresponding power parameter value P_{Iι1}; and

I₂ is an updated intensity value of the specific channel “I” and specific and specific iteration “ι”, for the second shifting-mode k=2, which is proportional to its corresponding power parameter value P_{Iι2}.

Aspects of disclosed embodiments pertain to a phase-locking subsystem, for locking temporary phase of each optical beam of a plurality of channel optical beams propagated through channels of a coherent beam combining (CBC) system, wherein the phase-locking subsystem is configured to temporarily lock a phase of each channel optical beam, based on:
changing a phase-difference between a reference optical beam and each channel optical beam of each channel “I” of the CBC system, by shifting the phase difference Δφ_{I} by a set of “m” predetermined phase shifts δφₖ, wherein “k” is an integer number from 1 to m and “m” is an integer number larger than 1, defining thereby an “m” number of shifting-modes; and
controlling phase-locking of phase of each channel optical beam according to the phase of the corresponding channel optical beam that is associated with a value of a modes-parameter of the corresponding channel that complied with at least one locking criterion, wherein the modes-parameter value is determined based on values of an intensity related power parameter measured for all shifting-modes.

Aspects of disclosed embodiments pertain to a phase-locking subsystem for locking phases of an array of channel optical beams propagated through channels of a coherent beam combining (CBC) system, where the phase-locking subsystem may include at least:
a referencing unit configured to generate a reference optical beam;
a sampling unit configured to generate an array of sample optical beams, sampled from an array of channel optical beams, propagated via channels of the CBC system and cause optical interference between each part of the reference optical beam and a corresponding sample optical beam, generating thereby an array of corresponding interference optical signals; and
a processing and control unit, configured to control phase-locking of phase of each channel optical beam of each channel at least by performing the following steps for each channel “I” and channel optical beam's phase testing-iteration “ι”, for testing channel beam phase φ_{Iι}:
(i) sequentially changing a phase difference Δφ_{Iι} between the phase of the channel optical beam and the reference optical beam, by a discrete set of phase shifts δφₖ, where k=1 . . . m, “m” being an integer number larger than 1, defining a discrete sequence of “m” shifting-modes;
(ii) measuring updated power parameter value P_{Iιk} of the interference optical signal for each phase shift δφₖ, resulting in a corresponding set of 1 to m power parameter values, each associated with a different phase shift δφₖ, for the respective channel “I” and respective “ι” phase testing iteration, where the power parameter is associated with an intensity of the corresponding interference signal of the corresponding channel “I” and phase testing iteration “ι”;
(iii) determining an updated value of a modes-parameter R_{ιI}, mathematically related to all “m” detected power parameter values P_{Iιk} for the respective channel “I” and the respective phase testing iteration “ι”; and
(iv) controlling phase-locking of phase of each channel optical beam according to the phase of the corresponding channel optical beam that is associated with the value of the modes-parameter of the corresponding channel that complied with at least one locking criterion.

According to some embodiments, the changing of the phase difference between each sample optical beam and the reference optical beam may be carried out by one or more of:
(i) phase-modulating the reference optical beam by using a phase modulation device configured to modulate the entire reference optical beam, by a discrete sequence of phase shifts δφₖ;
(ii) phase shifting the phase of each channel optical beam and/or its corresponding sample optical beam, using a phase shifter (PS) of the respective channel, by a discrete sequence of phase shifts δφₖ; and/or
(iii) phase shifting each portion of the reference optical beam separately, by a discrete sequence of phase shifts δφₖ, using an array of phase modulators (PMs) located such that each PM receives therethrough and phase-modulates a different portion of the reference optical beam directed to interfere with a corresponding sample optical beam, wherein the sample optical beams are sampled from the output optical beams of the CBC system.

According to some embodiments, the at least one criterion according to which the phase of each channel optical beam is controllably locked depends on a currently desired phase distribution of a combined optical beam outputted from the CBC system. For example, the processing and control unit may further be configured to control desired phase distribution of the combined optical beam by setting a different locking criterion to each channel, for resulting with intentional specific phase-differences between the reference optical beam and each of the channel optical beam for each channel, such as to enable a desired phased-array beam manipulation of the combined optical beam, such as beam steering.

According to some embodiments, the at least one locking criterion may include at least one of:
an extremum value of the modes-parameter, such that the phase of the channel optical beam is locked to the phase φ_{Iι} that yielded the minimum or maximum modes-parameter Ru value or an absolute value thereof |R_{ιI}|; and/or
a minimum value of an absolute distance between the modes-parameter R_{ιI} and a predefined desired modes-parameter R_{d}: minimum of: |R_{d}−R_{ιI}|.

According to some embodiments, for each channel “I”, the overall number of phase testing iterations in each phase-locking session may be limited to a testing timeframe or to a predefined limiting number of testing iterations. For example, the phase-locking steps may be performable in an ongoing and/or repeated manner such that phase-locking sessions for each channel are repeatedly performed during operation of the CBC system.

According to some embodiments, the overall timeframe for each testing iteration may be limited to a predefined testing timeframe ΔTₜ that corresponds to an estimated timespan of a modulation-sequence Δtₘ, for measuring all “m” different phase shifting-modes for shifting difference between the reference optical beam and the corresponding sample optical beam for the particular channel “I”, to enable detecting all power parameter values of all “m” shifting-modes.

According to some embodiments, the number of shifting-modes is m=2. for example, the two different shifting modes may include a first shifting-mode, k=1, in which the phase difference between the phase of the reference and sample optical beam is shifted by δφ₁=0 and a the second shifting-mode, k=2, in which the phase difference is shifted by δφ₂=π/2.

According to some embodiments, in which the above two shifting modes are set for the shifting sequence, the modes-parameter Ru of channel “I” and testing iteration “ι” may be mathematically proportional or equal to

\sqrt{(Io₁−I₁)²+(Io₂−I₂)²}, wherein:

I₀₁ and I₀₂ are predefined constants of desired intensity values of the interference optical signal, respectively, for the first and second shifting-modes: k=1 and k=2;

I₁ is an updated intensity value of the specific channel “I” and specific iteration “ι” for the first shifting-mode k=1, which is proportional to its corresponding power parameter value P_{Iι1}; and

I₂ is an updated intensity value of the specific channel “I” and specific and specific iteration “ι”, for the second shifting-mode k=2, which is proportional to its corresponding power parameter value P_{Iι2}.

According to some embodiments, the at least one criterion according to which the phase of each channel optical beam is controllably locked may be adjustable based on a currently desired spatial phase distribution of a combined optical beam outputted from the CBC system.

### BRIEF DESCRIPTION OF THE FIGURES

The figures illustrate generally, by way of example, but not by way of limitation, various embodiments discussed in the present document.

For simplicity and clarity of illustration, elements shown in the figures have not necessarily been drawn to scale. For example, the dimensions of some of the elements may be exaggerated relative to other elements for clarity of presentation. Furthermore, reference numerals may be repeated among the figures to indicate corresponding or analogous elements. References to previously presented elements are implied without necessarily further citing the drawing or description in which they appear. The figures are listed below.

FIG. 1A shows a far field (FF) beam distribution of a CBC of multiple input optical beams having unsynchronized phases and randomly oriented polarizations.

FIG. 1B shows a FF beam distribution of a CBC of multiple input optical beams having synchronized phases and orderly oriented polarizations.

FIG. 2 shows a CBC system 1000 for combining M×N temporally coherent input optical beams, using a fast phase and polarization locking mechanisms, according to some embodiments.

FIG. 3A shows a FF beam distribution of a CBC of multiple input optical beams having unsynchronized phases and randomly oriented polarizations.

FIG. 3B shows a FF beam distribution of a CBC of multiple input optical beams having locked synchronized phases and locked and orderly oriented polarizations, using a CBC system with a phase and polarization locking mechanisms, according to some embodiments.

FIG. 4A shows combined output optical beam steering, according to some embodiments, based on reference optical beam steering using a CBC system having phase and/or polarization locking, in a case in which the reference optical beam has a planar wave-front, propagated such that the combined output optical beam is steered to a zero steering angle.

FIG. 4B shows combined output optical beam steering, according to some embodiments, based on reference optical beam steering using a CBC system having phase and/or polarization locking, in a case in which the reference optical beam has a planar wave-front, propagated such that the combined output optical beam is steered to a non-zero steering angle.

FIG. 4C shows combined output optical beam steering, according to some embodiments, based on reference optical beam steering using a CBC system having phase and/or polarization locking, in a case in which the reference optical beam has a parabolic wave-front, propagated such that the combined output optical beam is steered to a zero-steering angle.

FIG. 4D shows combined output optical beam steering, according to some embodiments, based on reference optical beam steering using a CBC system having phase and/or polarization locking, in a case in which the reference optical beam has a parabolic wave-front, propagated such that the combined output optical beam is steered to a non-zero steering angle.

FIG. 5A shows a CBC system configured to enable phase and/or polarization locking having a controllable phased array wave-front control mechanism including multiple phase control modules, according to some embodiments.

FIG. 5B shows the CBC system of FIG. 5A, used for wave-front steering control, according to some embodiments.

FIG. 5C shows the CBC system of FIG. 5A, used for wave-front collimation control, according to some embodiments.

FIG. 6 shows a process for CBC phase locking, according to some embodiments.

FIG. 7 shows a process for CBC polarization locking, according to some embodiments.

FIG. 8 shows combined output optical beam wave-front control process, using a CBC system with wave-front control, according to some embodiments.

FIG. 9 shows a process of a CBC system phase locking and combined output optical beam wave-front control, based on received target data.

FIG. 10 shows a flowchart, schematically illustrating a process of phase-locking phases of channel optical beams of a CBC system, based on a sequential predetermined shifting of a phase difference between a reference optical beam or parts thereof and each of the channel optical beams of the CBC system, according to some embodiments.

FIG. 11 shows a CBC system with a phase locking mechanism for phase locking phases of channel optical beams of the CBC system based on discrete phase-modulation of a reference optical beam, according to some embodiments.

FIGS. 12A-12B show a schematic illustration of a phase locking mechanism that is based on binary discrete phase-modulation of the reference optical beam, according to some embodiments: FIG. 12A shows a binary discrete reference optical beam phase-modulation based phase locking, done by phase shifting of the reference optical beam by a phase shift of δφ₁=0 or of δφ₂=π/2, for a specific phase φ_{Iι} of the channel optical beam respective to reverence beam phase (for example with respect to a zero state of the reference optical beam) receiving two different power parameter values at the photodetector (e.g., photodiode (PD_{I})) of the specific channel “I”′ for each interference optical signal received from interference of the reference optical beam with a channel optical beam of the CBC system at each of the two different shifting-modes; and FIG. 12B shows a simulated phase difference behavior over time, between a phase of the channel optical beam and the phase of the reference optical beam, when using a binary discrete reference optical beam's phase-modulation.

FIG. 13 is a flowchart, schematically illustrating a process for phase locking of phases of channel optical beam of a CBC system, based on discrete phase-modulation of a reference optical beam, according to some embodiments.

### DETAILED DESCRIPTION

Coherent beam combining (CBC) aims to combine a plurality of temporally coherent input optical beams having the same optical wavelength or overlapping wavelength bands into a single coherent combined optical beam of a single wavelength or a narrow wavelengths band. Implementations of CBC often require maintaining a high beam quality, e.g., enabling high far field (FF) spatial and/or spectral beam coherency.

In some cases, a plurality of optical amplifiers such as fiber lasers (e.g., doped fibers) can be used to provide the input optical beams, enabling guiding light emanating from one or more light sources and power scaling the light guided therethrough.

The term “doped optical fiber” or “doped fiber” relates to any type of optical fiber doped with one or more elements such as, yet not limited to, erbium, dysprosium, ytterbium, neodymium, thulium, praseodymium, and/or holmium.

The term “optical beam”, “light beam” and/or “beam” used (interchangeably) herein may refer to any propagating electromagnetic signal, field and/or wave in the optical wavelengths range.

The term “beam quality” may relate to any one or more beam characteristics, such as, yet not limited to: wave-front (profile) quality, beam waist, beam radius, beam divergence, beam intensity/amplitude, beam brightness level (radiance), phase deviation (phase coherence), and the like and/or the maintaining over time and/or distance of these beam characteristics.

The term “temporally coherent optical beams” or “temporally coherent input optical beams”, used herein, may relate to multiple optical beams having correlated electromagnetic fields, e.g., where the frequency bandwidth Δf of the optical beams is conversely proportional to a temporal coherence time. For example, coherent optical beams may be temporally coherent by having the same signal modulation, the same or overlapping frequency/wavelength and/or the same or overlapping frequency/wavelength bandwidths.

In order to achieve CBC of FF high beam quality, the phases and polarization of the input optical beams that are to be combined should be controlled such that the phase/polarization is identical for all input optical beams, or such that the phases of the input optical beams are at desired specific differences from one another (e.g., in case of FF beam steering).

In many cases the input optical beams are of unknown phase and/or polarization, where the phase and/or polarization of each input optical beam may be unstable, i.e., rapidly change over time causing phase asynchronization between the input optical beams, which dramatically affects the FF beam quality of their combined optical beam.

Light source(s) and optical waveguides, such as fiber lasers, used as sources of the input optical beams, may be highly sensitive to environmental conditions and/or changes in those conditions such as trembling, quakes, temperature etc. such that under some environmental conditions the phase of an input optical beam may significantly change in a range of between every few milliseconds to every few microseconds. Typically, polarization changes in a range of between every few seconds to every tenth of a second, under destabilizing conditions. The phase of an input optical beam typically changes at a pace that is of several scales faster than the pace of changes in the polarization, when under destabilizing conditions.

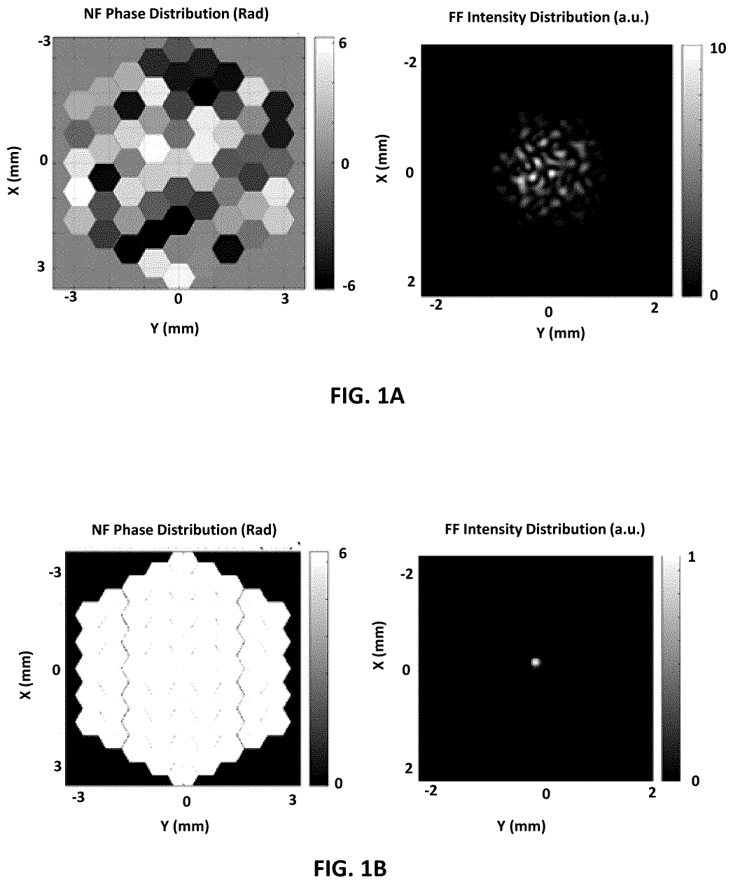

FIG. 1A shows a FF beam distribution of a CBC of multiple input optical beams having unsynchronized phases and randomly oriented polarizations. It is evident that the FF wave-front of the combined beam, in this case, will show scattered distribution of light, with no central lobe.

FIG. 1B shows a FF beam distribution of a CBC of multiple input optical beams having synchronized phases and orderly oriented polarizations. It is evident that the FF wave-front of the combined beam, in this case, will show a central lobe concentrating most of the combined optical beam FF power onto a much smaller angular spot size, performing a high-quality wave-front spatial distribution.

Aspects of disclosed embodiments pertain to systems and methods for CBC incorporating a closed-loop parallel phase locking mechanism and/or a parallel polarization locking mechanism that provide fast phase and/or polarization locking, to provide high quality and high-power CBC, that can endure various environmental and other conditions and changes of such conditions, causing rapid phase and/or polarization changes.

According to some embodiments, the CBC systems and methods enable combining multiple input optical beams (defining multiple channels) with automatic multi-channel close-looped phase and/or polarization locking, e.g., by using one or more reference optical beams and multiple optical detectors, where the phase and/or polarization locking is based entirely on intensity readings from the optical detectors and does not require calculation of the optimal phase and/or polarization for each channel, thereby allowing rapid phase and/or polarization locking.

According to some embodiments, the system is configured for CBC of a M×N array of multiple temporally coherent input optical beams defining M×N channels, each channel may be defined as all transformations of a respective single input optical beam, where M and/or N are non-zero integer numbers, and wherein M indicates number of lines in the array and N indicates the number of columns in the array.

The phase/polarization locking may be performed in an ongoing parallel closed-loop manner, to all channels simultaneously and separately.

According to some embodiments, the CBC systems and methods may be configured to:
provide a M×N array of temporally coherent input optical beams and a reference optical beam;
generate M×N output optical beams corresponding to the M×N input optical beams such that the output optical beams propagate in parallel along a first propagation direction (e.g., by using a M×N array of collimating elements);
divide each of the output optical beams such that a first portion of each of the output optical beams is directed towards the first propagation direction, all first portions of the output optical beams forming a combined output optical beam, and a second portion of each of the output optical beams is directed towards a second propagation direction and used as a sample optical beam;
direct the reference optical beam, such that the reference optical beam interferes with the sample optical beams, generating a plurality of corresponding optical interference signals;
provide a plurality of M×N optical detectors, each being positioned and configured to measure an overall intensity respective of each optical interference signal, to simultaneously and continuously generate a power output value, indicative of the detected intensity of its respective optical interference signal;
automatically and separately change a phase of each of the input optical beams, while comparing the measured power output value of its corresponding optical interference signal with at least one previously measured power output value generated by the respective optical detector; and
locking the phase of the input optical beam when reaching an extremum (maximum or minimum) power output value of its respective optical interference signal.

The above process may be performed such that the system phase-locks each channel separately when reaching a maximum intensity of its respective interference optical signal caused in a case of a constructive interference between the reference optical beam and the respective sample optical beam; or when reaching a minimum intensity of its respective interference optical signal caused in a case of a destructive interference between the reference optical beam and the respective sample optical beam.

Aspects of disclosed embodiments provide a system for coherent beam combining (CBC) that may include:
a light source, generating a source optical beam;
a beam splitting mechanism, configured to divide the source optical beam into an array of M×N temporally coherent input optical beams and a reference optical beam;
an array of M×N collimating elements, configured to direct each of the input optical beams through a separate collimating element, generating M×N output optical beams corresponding to the input optical beams passed through the collimating elements, such that the output optical beams are parallel to one another, defining a first propagation direction;
a beam splitting element, configured to divide each of the output optical beams such that a first portion of each of the output optical beams is directed towards the first propagation direction, all first portions of the output optical beams forming a combined output optical beam and a second portion of each of the output optical beams is directed towards a second propagation direction and used as a sample optical beam;
a plurality of optical detectors, each being positioned and configured to measure an overall intensity of a respective optical interference signal and output a corresponding power output value;
a control subsystem, configured to continuously receive measured power output values from each of the optical detectors, change a phase of each of the input optical beams, while comparing the measured power output value of the respective optical interference signal with at least one previously measured power output value from the respective optical detector, and lock the phase of the input optical beam when reaching an extremum power output value of its respective optical interference signal.

According to some embodiments, the changing of the phase of each input optical beam may be carried out directly based on the measured power output values of its respective optical interference signals, without calculating or estimating the correct phase and/or without producing any other signal associated therewith.

According to some embodiments, the system may be set to lock the phase and/or polarization of each respective channel only for a single extremum type for all channels, i.e. locking all channels when reaching their respective maximum intensity or when reaching their respective minimum intensity.

According to some embodiments, the changing of the phase and/or the polarization of each input optical beam is carried out directly based on the measured power output values of its respective optical interference signals, without calculating, estimating or previous knowledge of the correct phase/polarization and/or without producing any other signal associated therewith. This means, that only the identification (e.g., by comparison) of the maximum/minimum intensity of the respective channel is used to automatically lock the phase/polarization of the respective channel. For example, the phase of each input optical signal may be shifted upwards or downwards at equal phase steps differing from one another by a phase shift span Δϕ where for each phase shift, the intensity of the channel's respective interference optical signal is measured to find the extremum of the intensity of the respective channel within a time-span. According to some embodiments, the phase shift span Δϕ may be selectively controllable and/or adjustable.

According to some embodiments, the phase/polarization locking mechanism may be configured such that an updated intensity reading (i.e. last power output value of a respective detector) is only compared to one consecutive previously measured intensity reading of the respective optical detector of the respective channel. In other embodiments several previously measured intensity readings of the respective channel within a predefined detection time span may be used to locate the extremum intensity value.

The terms “reading”, “detector(s) reading”, “intensity reading(s)”, “intensity value” etc. may refer to and used interchangeably with the term “power output value(s)” of the optical detector(s).

According to some embodiments, the extremum value may only be identified after the phase has been shifted several times within a specific (short) time span (e.g., a microsecond), where the extremum is selected from those several measured intensities.

According to some embodiments, in order to lock the phase of a specific input optical beam, the system may be configured to shift the phase from its last state upwards or downwards e.g., by increasing or decreasing the phase, at a phase shift span Δϕ, while checking whether the intensity has been increased (in case of achieving a desired maximum extremum), in order to reach the location of the phase that provides the maximum intensity detector reading (herein “extremum phase”).

According to some embodiments, the polarization of the input optical beams may be linear or elliptical polarization, where the polarization controlling mechanism (i.e., “polarization locking mechanism”), may be configured for linear or elliptical polarization control.

According to some embodiments, the process of CBC may further include controlling one or more characteristics of a wave-front of the combined output optical beam, such as far field (FF) distribution of the wave-front, FF position of a central lobe formable by the combined output optical beams, central lobe focusing characteristics, wave-front spatial configuration, environmental optical aberrations corrections etc.

In some embodiments, the controlling of the one or more wave-front characteristics may be carried out by controlling direction of a wave-front of the reference optical beam (beam steering). The beam steering may be carried out, for example by mechanically moving of an output end of an optical waveguide from which the reference optical beam is outputted, and/or by mechanically changing a relative positioning between the optical waveguide output end and a focusing lens located within the pathway of the reference optical beam.

According to some embodiments, the controlling of the one or more wave-front characteristics may be carried out by using an M×N array of phase controlling modules (PCMs), where each PCM may be positioned and configured to control the phase of a different portion of the reference optical beam interfering with a respective sample optical beam.

According to some embodiments, the PCMs used may be electronically and/or digitally controllable. For example, liquid crystal spatial light modulators (SLMs) may be used as PCMs for the phased array wave-front control, for providing low-power electronically controllable PCMs. In other cases, an array of electronically and/or mechanically controllable steering mirrors may be used.

According to some embodiments, the controlling of the one or more characteristics of the wave-front of the combined output optical beam may be done according to a FF position of a target, towards which the combined optical beam is to be directed.

According to some embodiments, the position (e.g., distance and angular positioning) of the target in relation to the combined output beam position, may be detectable, e.g., by using a target detection device or system, configured to detect at least the position of the target (e.g., 3D detector) and optionally other characteristics values of the target such as target type, speed, material composition etc., and transmit target related data (herein also “target data”), indicative of the target characteristics values to the CBC system at least for wave-front control based on received target related data.

According to some embodiments, the phase and/or polarization of the reference optical beam (ϕref and Pref respectively) may be steady, i.e. having substantially slower change rate than the change rate of the phase and/or polarization of the input optical beams or show no phase and/or polarization change over time.

According to some embodiments, the phase locking may be carried out by having the phase of all input optical beams synchronized with the phase of the reference optical beam e.g., equal to the phase ϕref of the reference optical beam or, in case of wave front steering, having each phase of each channel being shifted at a desired shift rate Δϕsteer in respect to one or more adjacent channels.

For example, in case an angle of radiation θ_{beam,x} is desired (assuming a case in which only the x direction is treated and the distance between adjacent segments is equal throughout the M×N array along x and y directions) then the following phase distribution is required:

$${φ}_{steering} ( j ) = \frac{j \cdot Δ {x}_{seg} \cdot 2 π \cdot {θ}_{x , beam}}{{λ}_{laser}}$$

Where Δx_{seg} is the size of the segment at the array system output and Δₗₐₛₑᵣ is the wavelength of the laser (light source). The same holds for the case of tilted beam θ_{beam,y} is desired for the y direction:

$${φ}_{steering} ( i ) = \frac{i \cdot Δ {y}_{seg} \cdot 2 π \cdot {θ}_{y , beam}}{{λ}_{laser}}$$

Where the value of the maximal phase difference between adjacent segments should be smaller than 2π.

According to some embodiments, the input optical beams and the reference optical beam may emanate from the same single light source or different light sources.

According to some embodiments, the input optical beams may emanate from a single light source or multiple light sources.

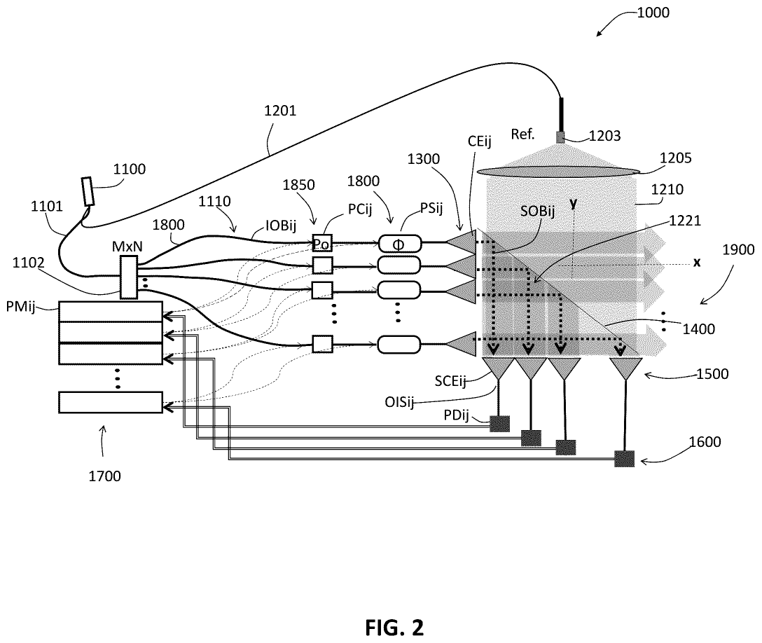

Reference is now made to FIG. 2, schematically illustrating a CBC system 1000 for combining M×N temporally coherent input optical beams (IOBs), using a fast phase and polarization locking mechanisms, according to some embodiments.

The CBC system 1000 may include:
a single light source 1100, configured to output light of a single wavelength λ0 or a narrow wavelengths band Λλ0;
a beam splitting mechanism for dividing the output light from the light source 1100 into a reference optical beam (ROB) 1210 and a M×N IOBs 1110;
an array of M×N phase shifters (PSs) 1800, each PSij being configured for controlling the phase of a respective (different) IOBij of a respective ij channel;
an array of M×N polarization controllers (PCs) 1850, each PCij being configured for controlling polarization of a respective (different) IOBij of a respective ij channel;
a M×N array of collimating elements (CEs) 1300, each CEij being positioned and configured to collimate a respective IOBij of a different respective ij channel;
a beam splitter 1400, configured and positioned such as to simultaneously divide the incoming M×N IOBs 1110 into M×N sample optical beams (SOBs) 1221 and a combined output optical beam (COOB) 1900, where the COOB 1900 is directed towards a first a first propagation direction, defining an axis x and the SOBs 1221 are directed towards a second propagation direction defining an axis y angular to axis x (where x may be perpendicular to y), where the ROB 1210 may be directed along they axis defined by the propagation direction of the SOBs 1221, so as to enable the SOBs 1221 to optically interfere with the ROB 1210;
an M×N array of optical detectors such as point detectors (PDs) 1600, each PDij being configured and positioned such as to detect intensity of a respective optical interference signal (01S) i.e., OISij, which is a signal formed due to the optical interference between a respective SOBij and the ROB 1210, where each PDij may be configured to output a power output value indicative of the measured intensity of the respective channel ij at a respective time;
a control subsystem 1700, being associated with the M×N arrays of PDs 1600, PSs 1800 and PCs 1850 for enabling ongoing and parallel receiving of power output values from each the PDs 1600, and controlling phase and/or polarization of each channel, based on its respective received power output value.

According to some embodiments, the control subsystem 1700 may include an array of M×N processing modules (PMs), each PMij being configured to receive power output values of a respective PDij and control, based on received power output values from the respective PDij, the phase and polarization of the respective IOBij via the respective PCij and PSij.

According to some embodiments, the controlling of the phase and/or polarization of a respective IOBij may be carried out by gradually increasing or decreasing the phase and/or gradually changing the polarization state, e.g., such as to provide, for example, an increase in the intensity (power output value) in the PDij reading, for locking the phase and/or polarization upon reaching a maximum interference optical signal value. This can be done by comparing a currently PDij reading with one or more previously measured intensities of the respective ij channel. According to some embodiments, it may be required to step back from a current phase and/or polarization value once the intensity extremum is passed.

According to some embodiments, the control subsystem 1700 may include one or more processing, control and/or memory modules, for enabling (temporary and/or long term) storage of current and previously measured power output values of each PD, for processing the received power output values for identification of an extremum phase and/or polarization of each channel and/or for controlling at least the PCs 1850 and/or the PSs 1800 for optimal (lock) phase/polarization identification and for phase/polarization locking of each channel e.g., by sending control commands that indicate only increase/decrease direction for the phase/polarization shift.

According to some embodiments, the phase and/or polarization control may also include controlling the phase and/or polarization shift span. For example, the phase shift span may be reduced once an area in which an extremum intensity is identified, to fine-tune the phase locking.

According to some embodiments, as illustrated in FIG. 2, the CBC system 1000 may further include:
a first optical waveguide 1101, which may be an optical fiber, connecting to one output node of the light source 1100 and configured to guide the light from the light source 1100 to a beam dividing device 1102 configured to device the light guided by the first optical waveguide 1101 into the M×N IOBs 1110, e.g., by having M×N optical fibers guiding the M×N IOBs 1110;
a second optical waveguide 1201, such as a second optical fiber, connecting to a second output node of the light source 1100 and configured for guiding the light to its distal fiber end, which may be held by a ferrule holder element 1203 for outputting therefrom the ROB 1210; and
a reference beam collimator 1205 such as one or more collimating lenses, mirrors, and/or a diffractive optical element (DOE), position in respect to the positioning of the output end of the second optical waveguide e.g., the edge of the holder element 1203 such that the ROB 1210 is to be collimated (e.g., by positioning the reference beam collimator 1205 at the focal plane and/or point of the reference beam collimator 1205).

According to some embodiments, as shown in FIG. 2, the CBC system 1000 may further include a M×N array of sampling collimating elements (SCEs) 1500, each SCEij being positioned and configured to intensify (e.g., by focusing) received light signal resulting from interference of the SOBij and the ROB 1210, of respective ij channel, onto a respective PDij.

According to some embodiments, the light source 1100 may include any type of light source that can output light at a single wavelength and/or a single narrow wavelengths band, such as a light emitting diode (LED), a monochromatic and/or tunable laser device etc.

According to some embodiments each PSij may be configured to control the phase of the respective IOBij by being electronically controlled and/or computer-controlled, e.g., by having its respective PMij being configured to change the phase based on received signal power value, input voltage or current value etc., applied to the respective PSij. The received signal power value may only be indicative of the phase shift direction (increase or decrease).

According to some embodiments each PMij may be configured to control the polarization of the respective IOBij by being electronically controlled and/or computer-controlled, e.g., by having its respective PMij being configured to change the polarization based on received signal power value, input voltage or current value etc., applied to the respective PMij. The received signal power value may only be indicative of the polarization deviation state (e.g., in case of an elliptic polarization, changing ellipticity and/or angle of the polarization vector(s)).

According to some embodiments, each PSij may include any type of phase shifting device and/or element configured to receive control commands (e.g., input power/voltage change), and shift the phase of the respective IOBij accordingly within a time span that is preferably faster than the natural IOBs phase changes time rates. The PSs 1800 may include for example, spatial light modulators (SLMs), devices including electrically/electronically controllable deformable mirrors, micro-electro-mechanical systems (MEMS), such as micro-electro-mechanical optics (e.g., mirrors), etc.

According to some embodiments, each PCij may include any type of polarization controlling device and/or element configured to receive control commands (e.g., input power/voltage change), and change the polarization state of the respective IOBij accordingly within a time span that is preferably faster than the IOBs natural polarization changes time rates. The PCs 1850 may include for example, piezoelectric element(s) based controllers, LiNO2 (LN) controllers, etc.

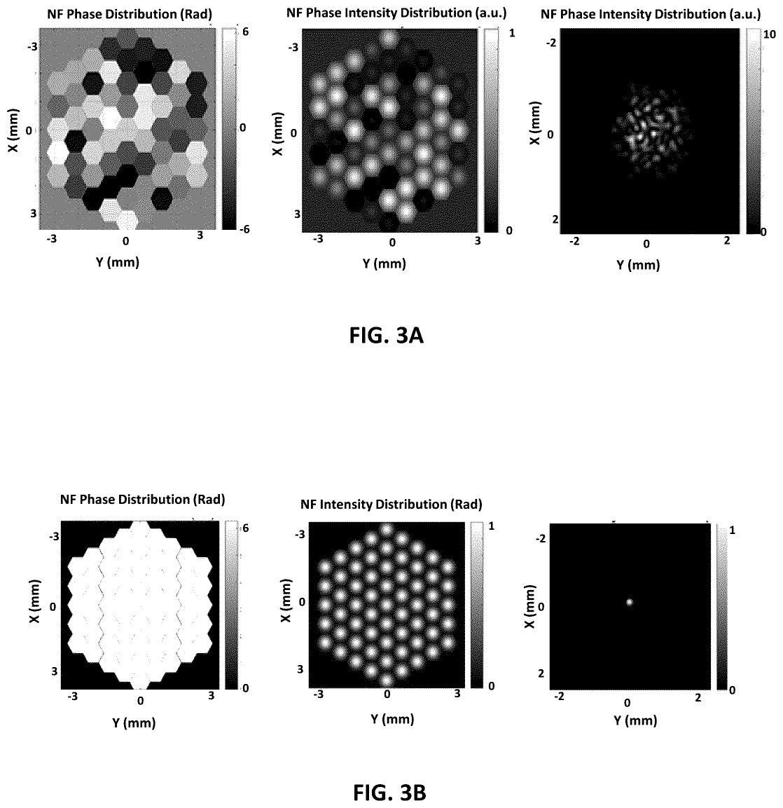

FIGS. 3A and 3B show resulting effect of using a fast CBC system with a phase lock mechanism as illustrated above: FIG. 3A shows a resulting FF beam distribution of a CBC of multiple input optical beams having unsynchronized phases and polarizations and FIG. 3B. show a result of using fast CBC system having the phase lock mechanism.

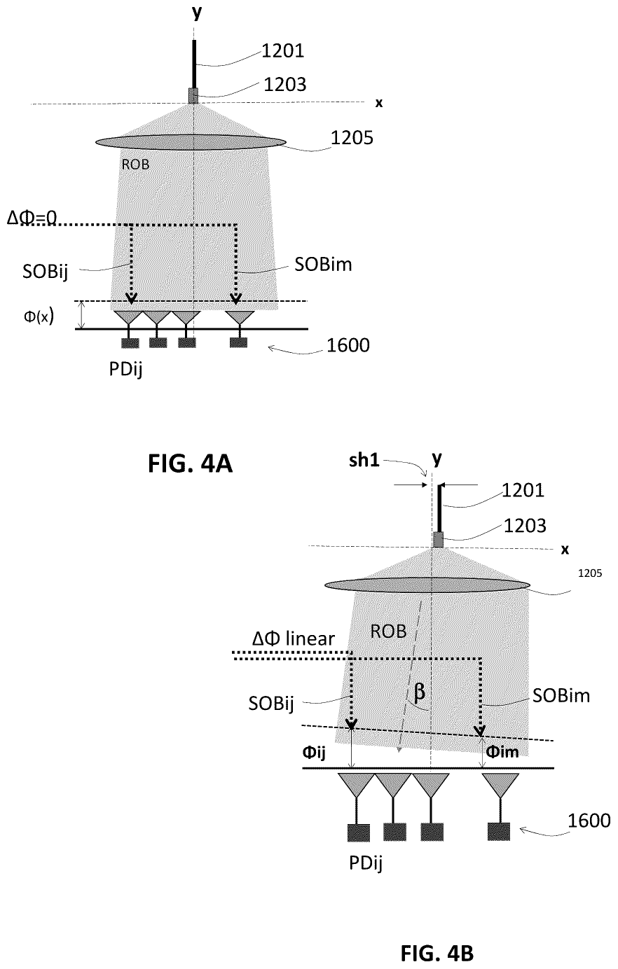

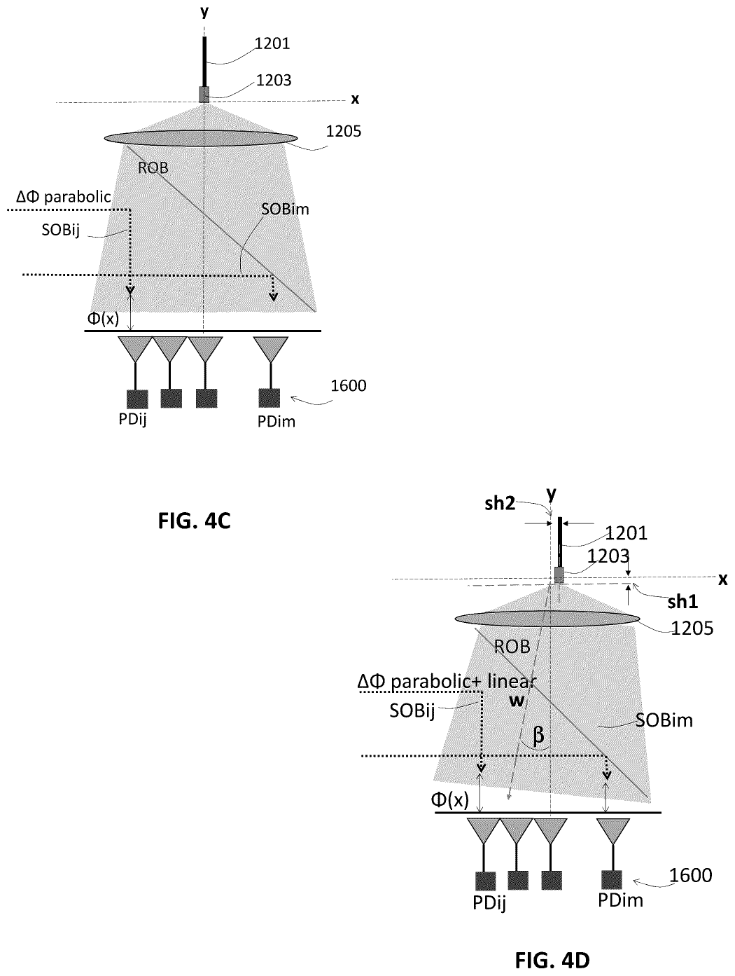

Reference is now made to FIGS. 4A, 4B, 4C and 4D showing a COOB 1900 wave-front control mechanism, enabling beam steering of the COOB 1900 by controlling a relative positioning between the reference beam collimator 1205 and the holder element 1203 holding an output node of the second optical waveguide 1201 guiding the reference optical beam (ROB), according to some embodiments.

FIG. 4A shows a ROB having a planar wave-front, propagated along the y axis. In this case, both the holder element 1203 and the reference beam collimator 1205 are positioned such that the planar ROB is propagated along the axis y where the focal point of the reference beam collimator 1205 is also located. In this configuration, all SOBs are directed through the same optical path length (OPL), and in parallel to the propagation direction of the ROB, where upon operation of the CBC system 1000 the phases and/or polarizations of all channels will automatically lock to the same phase and/or polarization resulting in a COOB 1900 having a planar wave-front that is steered (directed I) in parallel to the x axis (perpendicular to the direction of the ROB).

FIG. 4B shows a ROB having a planar wave-front, propagated angularly to the y axis, e.g., at a non-zero angle β in respect to the y axis. The resulting COOB in that case will be at angle −β.

In this case, the holder element 1203 is located with a shifted distance from the axis defined by the focal point of the reference beam collimator 1205 e.g., by shifting the holder element 1203 and/or the reference beam collimator 1205 along the x axis. In this configuration, each SOB of each j column of the M×N channels is directed through a different optical path length (OPL) and interferes with the angularly shifted ROB. In this case, upon operation of the CBC system 1000, the phases and/or polarizations of adjacent channels of a respective column j will automatically lock to different phases and/or polarizations according to:

Δx_{steering}=F₁·β

Where F_{I} is the focal length of the beam collimator 1205. The automatic phase difference between adjacent channels (segments) will be:

$${Δφ}_{steering} = \frac{- Δ {x}_{seg} \cdot 2 π \cdot {β}_{x , beam}}{{λ}_{laser}}$$

resulting in a COOB 1900 having a planar wave-front that is steered (directed) angularly to the x axis, where the different phases and/or polarizations will be automatically locked (without having to calculate them) upon reaching the extremum intensity reading from their respective PDs, thereby provide fast, automatic phase/polarization locking with optimal wave-front steering.

FIG. 4C shows a ROB having a parabolic wave-front, propagated in parabolic symmetry about the y axis. In this case, both the holder element 1203 and the reference beam collimator 1205 are positioned such that the parabolic ROB is propagated symmetrically about the axis y where the focal point of the reference beam collimator 1205 is also located. In this configuration, upon operation of the CBC system 1000 the phases and/or polarizations of all channels will automatically lock to the optimal phases and/or polarizations resulting in a COOB 1900 having a parabolic wave-front that is steered (directed I) in parallel to the x axis (perpendicular to the direction of the ROB).

FIG. 4D shows a ROB having a parabolic wave-front, propagated in symmetry about and axis w which forms a non-zero angle β with the y axis. In this case, the holder element 1203 and the focal point of the reference beam collimator 1205 may be shifted from one another at sh1 along axis x and sh2 along axis y. This may be achieved by shifting (moving) the holder element 1203 and/or the reference beam collimator 1205 along the x and y axes.

In this configuration, upon operation of the CBC system 1000 the phases and/or polarizations of channels of a respective column j will automatically lock the optimal phases and/or polarizations resulting in a COOB 1900 having a parabolic wave-front that is steered (directed I) angularly, in respect to the x and/or y axes.

|According to some embodiments, in order to enable steering wave-front control, the CBC system 1000 may further include a steering mechanism that enable control (e.g., electronic-based and/or computer-based control) of one or more mechanical elements and/or devices for physically changing the relative positioning between the focal point axis of the reference beam collimator 1205 and the ROB initial output direction when exiting the reference beam optical waveguide output node.

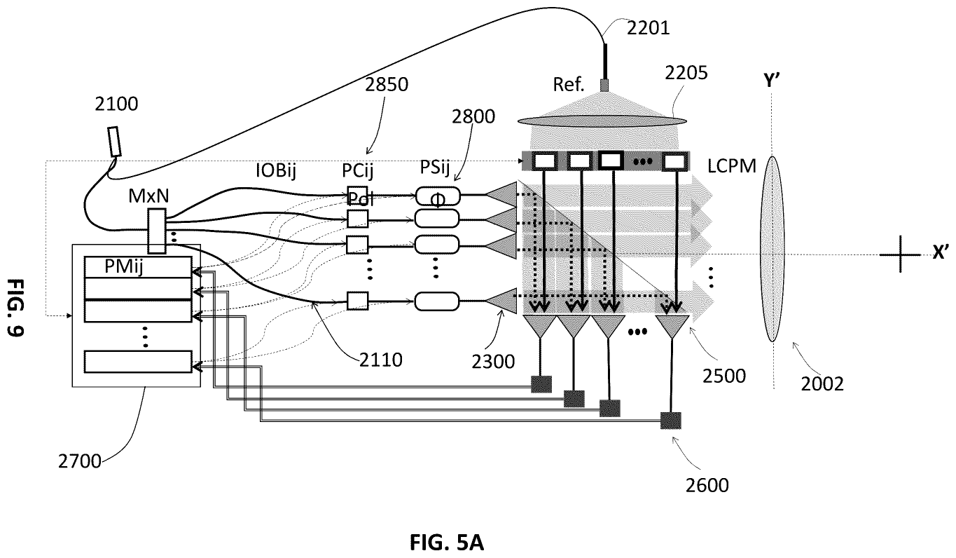

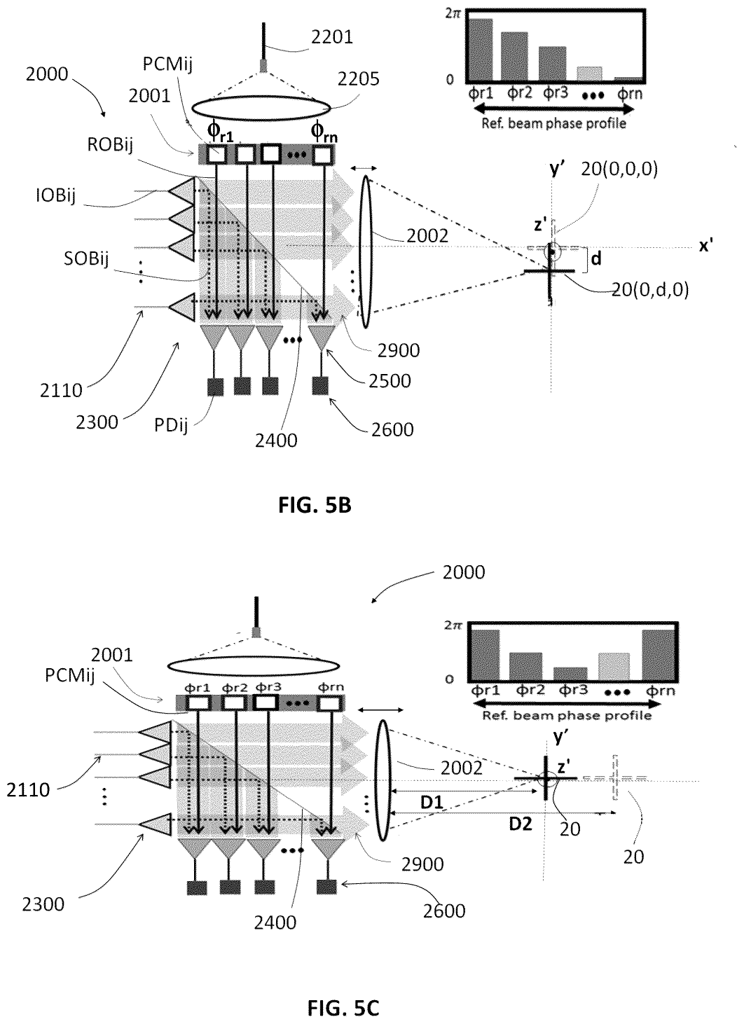

Reference is now made to FIGS. 5A, 5B and 5C showing a CBC system 2000 configured to enable phase and/or polarization locking as well as to control a wave-front of the combined output optical beam, by using an electronically controllable phased array wave-front control mechanism including multiple PCMs 2850, according to some embodiments.

The CBC system 2000 may include any mechanism for providing and controlling an M×N array of IOBs 2110 and directing thereof towards a beam splitter 2400 (e.g., by using an M×N array of collimating elements 2300), for dividing the IOBs 2110 into a COOB 2900 propagating to a first propagation direction along an x'axis, and to an array of M×N SOBS propagated along a second propagation direction (e.g., perpendicular to the first propagation direction parallel to axis y′), while controlling each phase and/or polarization of each separate IOB via M×N arrays of PSs 2800 and PCs 2850, respectively, e.g., by using a control subsystem 2700, operatively associated therewith.

The CBC system 2000 may further include a M×N array of electronically controlled and/or computer-controlled PCMs 2001, a M×N array of PDs 2600, a reference optical beam source 2201, a reference beam collimator 2205 and an output collimator 2002 configured to focus the COOB 2900.

The PCMs 2001 may be located between the beam splitter 2400 and the reference beam source 2201 (e.g., after the reference beam collimator 2205), so as to have each portion of the reference optical beam (herein reference optical beam (ROB) of each ij channel (i.e., ROBij)) being phase-shifted in a separately controllable manner, for example to enable beam steering of the COOB 2900.

The PMCs 2001 may include, for example, liquid crystal SLMs, each being separately electronically controllable, enabling to set a different phase for each ROB of each channel, e.g., to enable beam steering of the COOB 2900.

The phase and/or polarization locking may be carried out by a closed loop iterative changing of the phase and/or polarization of each IOBij, based on intensity readings from its associated PDij, such that the phase and/or polarization of each channel ij is locked when the intensity reading of the respective PDij of the channel is set on a maximum/minimum intensity value. The maximum intensity value, for example, for each channel ij, may be achieved, when the interference of the respective IOBij and ROBij is fully constructive, producing a respective maximum intensity of the OISij.

For example, if a target 20 is located over an x′z′ plane (as illustrated in FIG. 5B), at the FF from the CBC system 2000, then if the target is located at 0,0,0, location of the x′y′z′ axes (e.g., where x′ is defined by the propagation direction of the COOB 2900), the phases of all IOBs should be equal to one another. In this case, the PCMs may be set such that all phases of all ROBs are equal to one another, in order to enable the CBC system 2000 to automatically lock each of the IOBs 2110 upon reaching an extremum intensity value of their respective OISs. If the target is located at a shifted position, for example at a d shifted position from the 0,0,0 position of the x′y′z′ axes, (e.g., at a position of 0,d,0 as shown in FIG. 5B), then the phases of the ROBs of each column N, may each be set to a different value, in order to steer the wave-front of the COOB 2900 to the target 20 location 0,d,0, by having each of the IOBs 2110 automatically lock to the optimal (different) phase value, upon reaching maximum/minimum intensity value of their corresponding OISs.

According to some embodiments, an output beam collimating device 2002 such as one or more focusing lenses, may be used to enable controlling focusing positioning such as focal length of the COOB 2900.

In cases in which the wave-front control for the COOB 2900 additionally or alternatively requires focus control of the COOB wave-front, e.g., by controlling the focal point or plane of the COOB 2900, the output beam collimating device 2002 may enable mechanical shifting of relative positionings of one or more collimating elements (e.g., lenses) thereof, in an electronically and/or computer controllable manner.

FIG. 5C shows exemplary cases, in which the target 20 can be positioned along the x′ axis at a focal length D1 of the output beam collimating device 2002 or shifted a length D2 along the x′ axis, in the latter case, the output beam collimating device 2002 may be adjusted (e.g., by electronically controlling relative positioning of several lenses) to focus the COOB 2900 to a focal length of D2.

According to some embodiments, the CBC system 2000 may further include a M×N array of sampling collimating elements (SCEs) 2500, each SCEij being positioned and configured to focus light resulting from interference of the SOBij and the ROBij 1210, of respective ij channel, onto a respective PDij.

According to some embodiments, the IOBs 2110 and the ROB may all originate from a single monochromatic light source such as light source 2100.

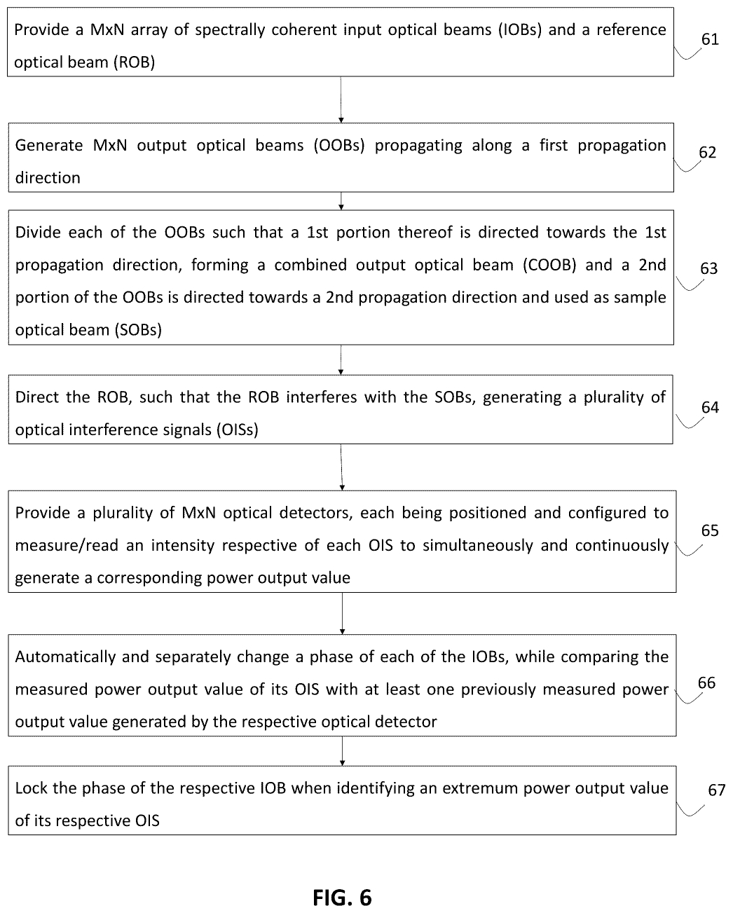

Reference is now made to FIG. 6 showing a process for CBC phase locking, according to some embodiments. The process may include:
providing a M×N array of temporally coherent input optical beams and a reference optical beam 61;
generating M×N output optical beams corresponding to the M×N input optical beams such that the output optical beams propagate along a first propagation direction 62;
dividing each of the output optical beams such that a first portion of each of the output optical beams is directed towards the first propagation direction, all first portions of the output optical beams forming a combined output optical beam and a second portion of each of the output optical beams is directed towards a second propagation direction and used as a sample optical beam 63;
directing the reference optical beam, such that the reference optical beam interferes with the sample optical beams, generating a plurality of optical interference signals 64;
providing a plurality of M×N optical detectors, each being positioned and configured to measure an intensity respective of each optical interference signal of the plurality of optical interference signals to simultaneously and continuously generate a corresponding power output value 65;
automatically and separately changing a phase of each of the input optical beams, while comparing the measured power output value of the respective optical interference signal with at least one previously measured power output value generated by the respective optical detector; wherein the changing of the phase of each input optical beam is carried out directly based on the measured power output value of its respective optical interference signal 66; and
locking the phase of each respective input optical beam when reaching an extremum power output value of its respective optical interference signal 67.

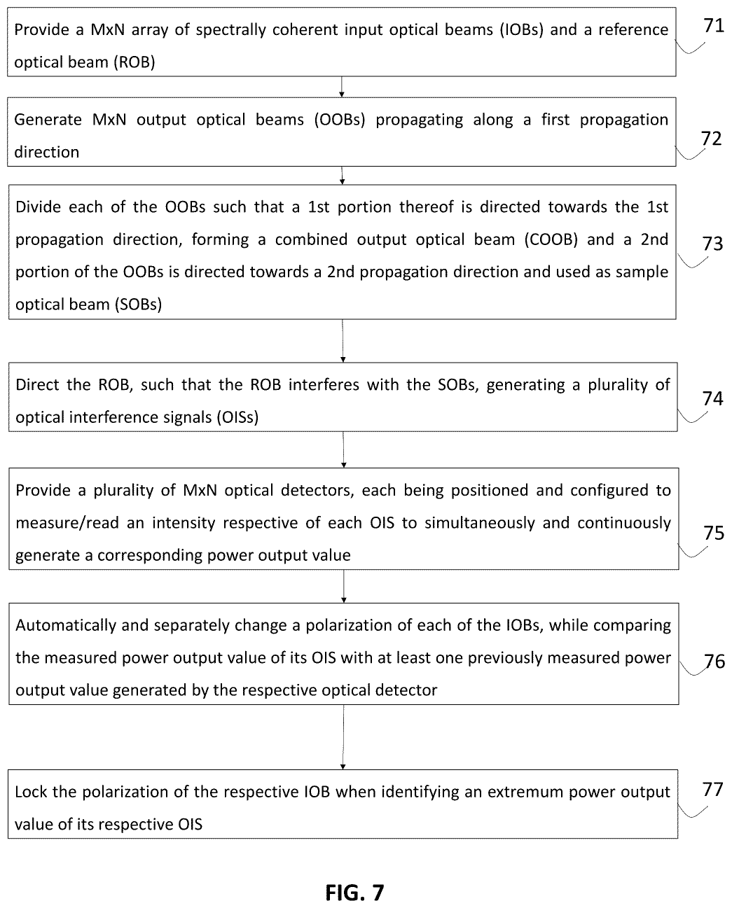

Reference is now made to FIG. 7 showing a process for CBC polarization locking, according to some embodiments. The process may include:
providing a M×N array of temporally coherent input optical beams and a reference optical beam 71;
generating M×N output optical beams corresponding to the M×N input optical beams such that the output optical beams propagate along a first propagation direction 72;
dividing each of the output optical beams such that a first portion of each of the output optical beams is directed towards the first propagation direction, all first portions of the output optical beams forming a combined output optical beam and a second portion of each of the output optical beams is directed towards a second propagation direction and used as a sample optical beam 73;
directing the reference optical beam, such that the reference optical beam interferes with the sample optical beams, generating a plurality of optical interference signals 74;
providing a plurality of M×N optical detectors, each being positioned and configured to measure an intensity respective of each optical interference signal of the plurality of optical interference signals to simultaneously and continuously generate a corresponding power output value 75;
automatically and separately changing a polarization of each of the input optical beams, while comparing the measured power output value of the respective optical interference signal with at least one previously measured power output value generated by the respective optical detector; wherein the changing of the polarization of each input optical beam is carried out directly based on the measured power output value of its respective optical interference signal 76; and
locking the polarization of each respective input optical beam when reaching an extremum power output value of its respective optical interference signal 77.

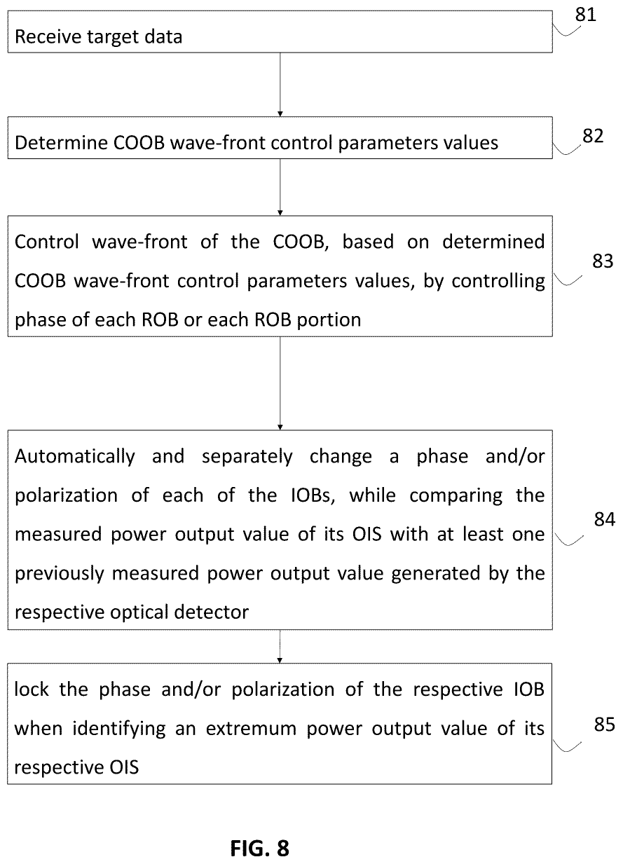

Reference is made to FIG. 8, illustrating a wave-front control process, using a CBC system with wave-front control, according to some embodiments. This process may include:
receiving target data 81, e.g., indicative of one or more target characteristics values such as a target positioning, movement characteristics values (such as speed), etc.;
determining control parameter(s) value(s) for COOB wave-front control 82 (e.g., determining focusing and/or steering related parameters values for focusing and/or steering the COOB towards the target, based on the target positioning target data);
controlling the wave-front of the COOB, based on determined control parameter(s) value(s) 83, e.g., by generating and transmitting control commands and/or control signals for electronically/computer controlling of a focusing device and/or of a steering mechanism that can controllably change phase of each portion of the reference optical beam or each reference optical beam;
automatically and separately changing the phase and/or polarization of each of the input optical beams, while comparing the measured power output value of the respective optical interference signal with at least one previously measured power output value generated by the respective optical detector; wherein the changing of the phase/polarization of each input optical beam is carried out directly based on the measured power output value of its respective optical interference signal 84; and
locking the phase and/or polarization of each respective input optical beam when reaching an extremum power output value of its respective optical interference signal 85.

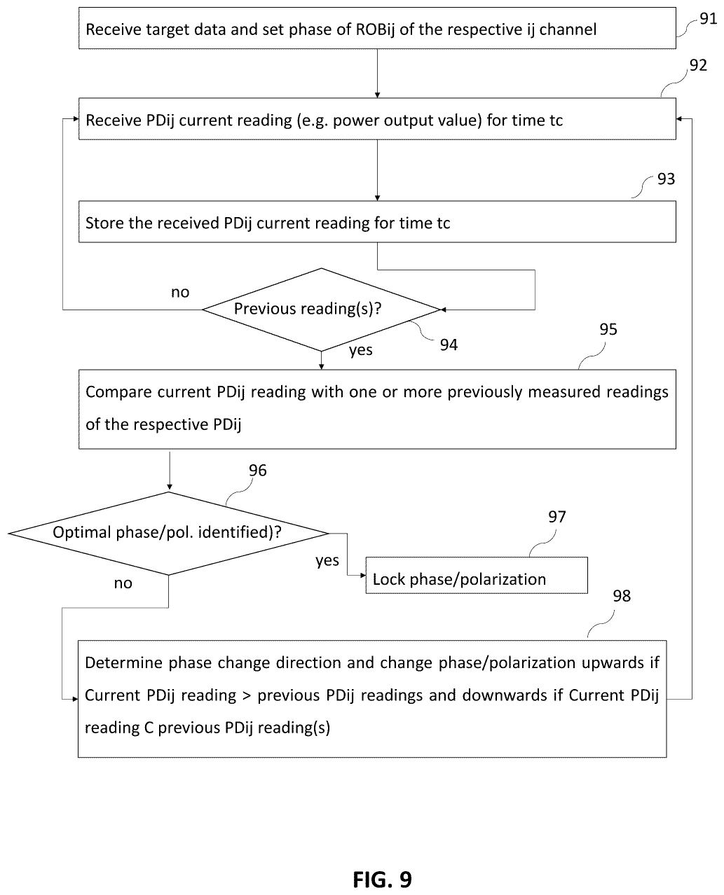

Reference is made to FIG. 9, illustrating an embodiment of a process of a CBC system phase locking and COOB wave-front control, using M×N channels and M×N PCMs, based on received target data. This process may include:
receiving target data and setting phase of each of the reference optical beams e.g., using the M×N array of PCMs, based on the received target data 91;
for each ij channel:
receiving PDij current intensity reading (at time tc) 92;
storing the received PDij current reading 93;
if the intensity reading of the respective channel is not the first 94 comparing the received PDij intensity reading with one or more previously received PDij intensity readings (e.g., limited number of previous intensity readings taken within a limited time-span) 95 and checking whether the current intensity reading is higher or lower than at least one of the one or more previously received intensity readings of the respective channel ij 96;
if an optimal phase of the IOBij that provides an extremum intensity reading within the time-span is identified 96, then the optimal phase is locked 97;
If the optimal phase is not identified, a phase change direction (e.g., increase or decrease) is determined and the respective phase of the IOBij is changed 98.

Steps 92-98 can be repeated for each channel and for each predefined time-span, for locking onto the optimal phase of each respective channel in a fast and efficient manner.

According to some embodiments, all phase and/or polarization locking mechanisms described above, allow extremely fast and efficient phase/polarization locking such that can enable locking the phase/polarization within a locking time Tiock that is faster than or equal to the input optical beam phase/polarization change rate regardless of the environmental or other conditions influencing the input optical beams phase/polarization value instabilities (e.g., change and/or phase/polarization values fluctuations rate).

Aspects of disclosed embodiments pertain to a phase locking subsystem and/or method, for locking temporary phase of each optical beam of a plurality of channel optical beams in a CBC system that is based on changing a phase difference between a reference optical beam and each channel optical beam of each channel “I” of the CBC system, by shifting the phase difference Δφ_{I} between the reference optical beam portion interfering with a respective sample optical beam, sampled from the respective channel optical beam, by a set of “m” predetermined phase shifts δφₖ, where “k” is an integer number from 1 to m and “m” is an integer number larger than 1.

The term “channel” used herein may relate to one or more optical paths of a single optical beam whether before and/or after passing through a beam combining element(s), system(s), unit(s), device(s), etc. A single channel optical path(s) may be at least partially guided via one or more waveguides such as via one or more optical fibers and/or through air or any other non-confining medium.

According to some embodiments, the phase-locking method may include at least the following steps:
(a) generating a reference optical beam;
(b) generating an array of sample optical beams, sampled from an array of channel optical beams, propagated via channels of a CBC system and causing optical interference between each part of the reference optical beam and a corresponding sample optical beam generating thereby an array of corresponding interference optical signals, e.g., by directing each sample optical beam such as to interfere with a different portion of the reference optical beam, using one or more optical devices/elements such as by using a beam splitter;
(c) for each channel “I” and channel optical beam's phase testing-iteration “ι” (out of multiple iterations of a testing session), for testing channel beam phase φ_{Iι}:
changing a phase difference Δφ_{Iι} between the phase of the channel/sample optical beam and the reference optical beam, by a discrete set of phase shifts δφₖ, (where k=1 . . . m and “m” is an integer number larger than 1);
measuring updated power parameter value PA of the interference optical signal for each phase shift δφₖ, resulting in a corresponding set of 1 to m power parameter values, each associated with a different phase shift δφₖ, for the respective channel “I” and respective “ι” channel phase testing iteration, where the power parameter may be associated with the intensity (such as the overall intensity) of the corresponding interference signal of the corresponding channel “I” and “ι” channel phase testing iteration;
determining an updated value of a modes-parameter R_{iI}, mathematically related to all “m” detected power parameter values P_{Iik} for the respective channel “I” and the respective channel phase testing iteration “ι”,
where sub-steps of step (c) may be repeated for a number of times, limited by a predetermined iterations timespan or a limited predefined number of iterations; and
(d) controlling phase locking of phase of each channel optical beam according to the phase of the corresponding channel optical beam that provided the value of the modes-parameter (of the corresponding channel) that complied with at least one locking criterion, such as, for example, the minimum modes-parameter value for the corresponding channel and iteration, from all measured/determined corresponding modes-parameter values.

According to some embodiments, the changing of the phase difference between the channel/sample optical beam and the reference optical beam may be carried out by one or more of:
(i) phase-modulating the reference optical beam (e.g., by using a phase modulation device) by a discrete sequence (set) of phase shifts δφₖ;
(ii) phase shifting the phase of each channel optical beam and/or the corresponding sample optical beam sampled therefrom, e.g., by using a phase shifter (PS) of the respective channel optical beam, e.g., configured to phase shift an input optical beam part of the respective channel optical beam; and/or
(iii) phase shifting each portion of the reference optical beam separately, by a discrete sequence (set) of phase shifts δφₖ, using an array of phase modulators (PMs), such as an array of SLMs, located such as to receive therethrough and phase-modulate different portions of the reference optical beam, where the sample optical beams are sampled from the output optical beams of the CBC system.

According to some embodiments, for each channel “I”, the overall number of testing iterations (which is larger than 1) in each phase-locking session is limited to a testing timeframe or to a predefined limiting number of testing iterations. For example, the phase locking method steps may be performable in an ongoing and/or repeated manner such that each phase-locking session for each channel is repeatedly performed during operation of the CBC system.

According to some embodiments, the power parameter value of each channel may be measured separately by using an array of optical detectors, each configured and positioned to measure intensity (such as overall intensity) related value of interference optical signals of a corresponding channel “I”.

According to some embodiments, the method steps may be performed by a phase locking subsystem that is embedded as part of the CBC system.

According to some embodiments, the input optical beams being coherently beam combined, may be arranged to propagate in parallel to one another such as to form a polygonal propagation formation such as in a rectangular, square, hexagonal, pentagonal, octagonal, or to form an oval or circular formation in the NF area, at least before being combined.

According to some embodiments, the channels and their corresponding elements may be arranged to form rectangular M×N arrays or may be arranged at a different spatial arrangement in which distances between adjacent channel-elements and/or optical beam propagation direction arrays are the same or different from one another.

According to some embodiments, the CBC system may include a CBC unit for coherently beam combining of an array of input optical beams, considered herein as part of the array of channel optical beams, such as to output a corresponding array of output optical beams (also considered as part of the array of channel optical beams), optionally propagated in parallel propagation direction, at least in the NF area.

The CBC unit may include one or more optical setups, elements and/or devices for combining the input optical beams, such as collimation array including an array of collimators for side-by-side CBC by collimation of each input optical beam. The CBC unit may additionally or alternatively include other elements for enabling beam combining and/or for improving FF beam quality of the combined optical beam and/or for improving and/or enabling steering capabilities of the CBC system, such as one or more corresponding arrays of beam shaping elements, one or more correcting elements or arrays thereof, for correcting optical errors and/or aberrations specific to the particular CBC system, etc.

According to some embodiments, the phase-locking methods and/or systems may be used for improving controlling each phase of each channel optical beam separately for enabling any beam steering such as phased-array beam steering of the combined optical beam in the near and/or far field whether the steering is aligned with or angular to the optical axis, parallel to the propagation direction of the combined optical beam in the near filed (NF) formed by an array of output optical beam, outputted from the CBC unit of the CBC system.

The above-described phase-locking systems, subsystems and/or method may be aimed, inter alia, to improve phase-locking speed, beam steering abilities such as beam steering control speed and/or accuracy, far field (FF) beam quality aspects such as reduced power/intensity/energy spatial distribution of the combined optical beam in a FF traversing plane (power in the bucket), reduced energy losses and increased energy concentration and the like, phase-locking accuracy, and the like.

According to some embodiments, there is provided a phase locking subsystem for locking phases of an array of channel optical beams propagated through channels of a coherent beam combining (CBC) system, the phase-locking subsystem comprising at least:
a referencing unit configured to generate a reference optical beam;
a sampling unit configured to generate an array of sample optical beams, sampled from an array of channel optical beams, propagated via channels of the CBC system and cause optical interference between each part of the reference optical beam and a corresponding sample optical beam, generating thereby an array of corresponding interference optical signals; and
a processing and control unit, configured to control phase-locking of phase of each channel optical beam of each channel at least by performing the following steps for each channel “I” and channel optical beam's phase testing-iteration “ι”, for testing channel beam phase φ_{Iι}:
(i) sequentially changing a phase difference Δφ_{Iι} between the phase of the channel optical beam and the reference optical beam, by a discrete set of phase shifts δφₖ, where k=1 . . . m, “m” being an integer number larger than 1, defining a discrete sequence of “m” shifting-modes;
(ii) measuring updated power parameter value P_{Iιk} of the interference optical signal for each phase shift δφₖ (e.g., by using an array of optical detectors also included in the phase-locking subsystem), resulting in a corresponding set of 1 to m power parameter values, each associated with a different phase shift δφₖ, for the respective channel “I” and respective “ι” phase testing iteration, where the power parameter is associated with an intensity of the corresponding interference signal of the corresponding channel “I” and phase testing iteration “ι”; and
(iii) determining an updated value of a modes-parameter R_{ιI}, mathematically related to all “m” detected power parameter values P_{Iιk} for the respective channel “I” and the respective phase testing iteration “ι”; and
(iv) controlling phase-locking of phase of each channel optical beam according to the phase of the corresponding channel optical beam that is associated with the value of the modes-parameter of the corresponding channel that complied with at least one locking criterion.

According to some embodiments, the changing of the phase difference between each sample optical beam and the reference optical beam may be carried out by one or more of:
(i) phase-modulating the reference optical beam by using a phase modulation device configured to modulate the entire reference optical beam, by a discrete sequence of phase shifts δφₖ;
(ii) phase shifting the phase of each channel optical beam and/or its corresponding sample optical beam, using a phase shifter (PS) of the respective channel, by a discrete sequence of phase shifts δφₖ; and/or
(iii) phase shifting each portion of the reference optical beam separately, by a discrete sequence of phase shifts δφₖ, using an array of phase modulators (PMs) located such that each PM receives therethrough and phase-modulates a different portion of the reference optical beam directed to interfere with a corresponding sample optical beam, wherein the sample optical beams are sampled from the output optical beams of the CBC system.

Using a multimode based two or more intensity measurements for different “m” number of phase shifts between the reference optical beam and the respective channel/sample optical beam, for each channel, may dramatically improve accuracy in phase locking of the phase of each channel optical beam and therefore dramatically improve corresponding control over the spatial phase distribution of the outputted combined optical beam in the near and in the far fields, without affecting timing/speed at which the processing and phase locking should be done, which is limited to the timing at which the phase of each channel is estimated to randomly/naturally change.

According to some embodiments, the at least one criterion, according to which the phase of each channel optical beam is locked, may depend at least on a desired spatial phase distribution of the outputted combined optical beam, outputted from the CBC system. This may mean that the desired relative phase difference between each two adjacent channel optical beam may be equal to all channels or different from one channel to another, e.g., in order to perform beam steering of the combined outputted optical beam. For example, when the combined optical beam is to be steered in parallel to the optical axis, all phases of the channel optical beams may be required to be of the same or extremely close phase, i.e., having a zero-phase difference therebetween. If the output combined optical beam is to be steered (via a phased-array beam steering), each pair of adjacent channels may be required to be of a non-zero phase difference so as to achieve a spatial phase distribution of the combined optical beam at the NF area in order to (phased array) beam steer the combined beam to an off-axis location at a FF area in respect to the location and main optical axis of the CBC system.

According to some embodiments, the phase difference Δφ_{Iιk} between the reference optical beam and each channel/sample optical beam of each channel may be achieved by phase modulation of the reference optical beam, using at least one phase modulation device configured to phase-modulate the reference optical beam, according to a preset repeatable discrete phase shifting-sequence, such that at each given timeframe Δtₘ of the shifting-sequence, the reference optical beam is outputted at the “m” number of different and sequential shifting-modes.

According to some embodiments, in which the entire reference optical beam is phase-modulated, to achieve the sequential shifting of the phase difference between the reference and channel/sample optical beams, the phase-modulation of the reference optical beam may be done by using at least one phase-modulation device such as a “reference phase shifter” or “phase modulator”, configured at least for phase-shifting of optical beams.

According to some embodiments, the (phase-modulated) reference beam may be interfered with samples of output optical beams of the CBC system (forming the array of sample optical beam), by splitting each output optical beam, e.g., by using a beam splitter, similarly to as described above for the CBC system 2000 of FIGS. 5A-5C, outputted from one or more CBC devices such as a collimation array and/or a beam shapers array(s), to generate and output an array of interference optical signals caused by interference of each sample optical beam with a corresponding portion of the phase-modulated interference optical beam. Intensity of interference optical signal of each channel “I” may be detectable via a different optical detector (e.g., by use of an array of optical detectors, as mentioned above).

According to some embodiments, the phase of each channel optical beam may be changed (shifted) to an updated phase φ_{Iξ}, where for each channel “I” and each phase φ_{Iι} of the corresponding channel optical beam at least the following operations/steps are performable:
(i) receiving an updated value P_{Iιk} of the power parameter of the respective shifting-mode “k”, from the optical detector of the corresponding channel “I” and the corresponding current channel optical beam phase φ_{Iι} of the channel “I”, where k=1 . . . m; and
(ii) determining an updated value of a modes-parameter R_{ιI}, the modes-parameter Ru, representing mathematical relation between all detected values P_{Iιk} of the power parameter of all shifting-modes k=1 tom of the respective channel “I” for the specific channel optical beam phase φ_{Iι}; and
locking phase of the channel optical beam of the corresponding channel “I” based on values of the modes-parameter for several phase changes of the channel optical beam.

For example, the phase of the channel optical beam may be (temporarily) locked to a locking phase φ_{Iι} for which the value of the modes-parameter R_{ιI} complies with (meets) at least one predefined locking criterion.

The above steps/action may be performable in a convergency manner, in which, the phase φ_{Iι} of the channel optical beam, of channel “I”, is increased or decreased by a constant (and optionally reprogrammable/adjustable) phase shift Δ [symbol] according to a distance of the modes-parameter value from a predefined threshold and/or according to whether the modes-parameter value is higher or lower than its value for one or more previously set channel optical beam phases φ_{Iι-v}.

According to some embodiments, the number of iterations (for increasing/decreasing phase shift of the channel optical beam—defining the number of testing iterations) may be limited so that the channel optical beam's phase locking will not exceed timing of estimated natural phase change occurrence of the channel optical beam.

According to some embodiments, for each channel “I”, the channel optical beam's phase φ_{Iι} may be maintained for a phase shift timeframe ΔTₚₛ that corresponds to (e.g., equal to and/or higher than) the timeframe of the modulation-sequence Δtₘ, to enable detecting all power parameter values of all “m” shifting-modes of the reference optical beam, for the same channel optical beam's phase φ_{Iι}.

According to some embodiments, a desired phase distribution of the combined optical beam may be controlled, by setting a different locking criterion to each channel, for causing intentional specific phase-differences between the channel optical beams, for enabling a desired phased-array beam steering of the combined optical beam.

According to some embodiments, the at least one locking criterion may include at least one of:
an extremum value of the modes-parameter, such that the phase of the channel optical beam is locked to the phase φ_{Iι} that yielded the minimum or maximum modes-parameter Ru value or an absolute value thereof |R_{ιI}|, between all modes-parameter values determined for all phases of the channel optical beam being tested in each phase locking session; and/or
a minimum value of an absolute distance D between the modes-parameter R_{ιI} and a predefined desired modes-parameter R_{d}: minimum of: D_{ιI}=|R_{d}−R_{ιI}|, between all modes-parameter values determined for all phases of the channel optical beam being tested in each phase-locking session.

According to some embodiments, for each channel “I”, the overall number of testing iterations in each phase-locking session may be limited to a testing timeframe or to a predefined limiting number of testing iterations. For example, the phase-locking actions or steps may be performable, for each channel, in an ongoing and/or repeated manner such that phase-locking sessions for each channel are repeatedly performed during operation of the CBC system.

According to some embodiments, the number of shifting-modes, for each iteration (i.e., for each tested channel phase φ_{Iι}) may be m=2 (defining a “binary discrete phase modulation” of the reference optical beam). Such binary discrete phase shifting of the phase difference between the reference and corresponding channel optical beam, may include, for example, using two predefined shifting modes: a first shifting-mode, k=1, in which the phase difference is not shifted: δφ₁=0, and in a second shifting-mode, k=2, in which the phase shift is of a predefine shift value such as δφ₂=π/2.

In such binary shifting, the modes-parameter R_{ιI} of channel “I” and channel optical beam phase φ_{Iι}, may be mathematically related or equal to \sqrt{(Io₁−I₁)²+(Io₂−I₂)²}, where:

I₀₁ and I₀₂ are predefined constants of desired intensity values of the interference optical signal, respectively, for the first and second shifting-modes: k=1 and k=2;

I₁ is an updated intensity value of the specific channel “I” and specific channel optical beam phase φ_{Iι}, for the first shifting-mode k=1, which is proportional to its corresponding power parameter value R_{Iι1}; and

I₂ is an updated intensity value of the specific channel “I” and specific channel optical beam phase φ_{Iι}, for the second shifting-mode k=2, which is proportional to its corresponding power parameter value P_{Iι2}.

According to some embodiments, the power parameter value of each corresponding channel “I”, is related to the overall intensity of the corresponding interference signal of the respective channel “I”.

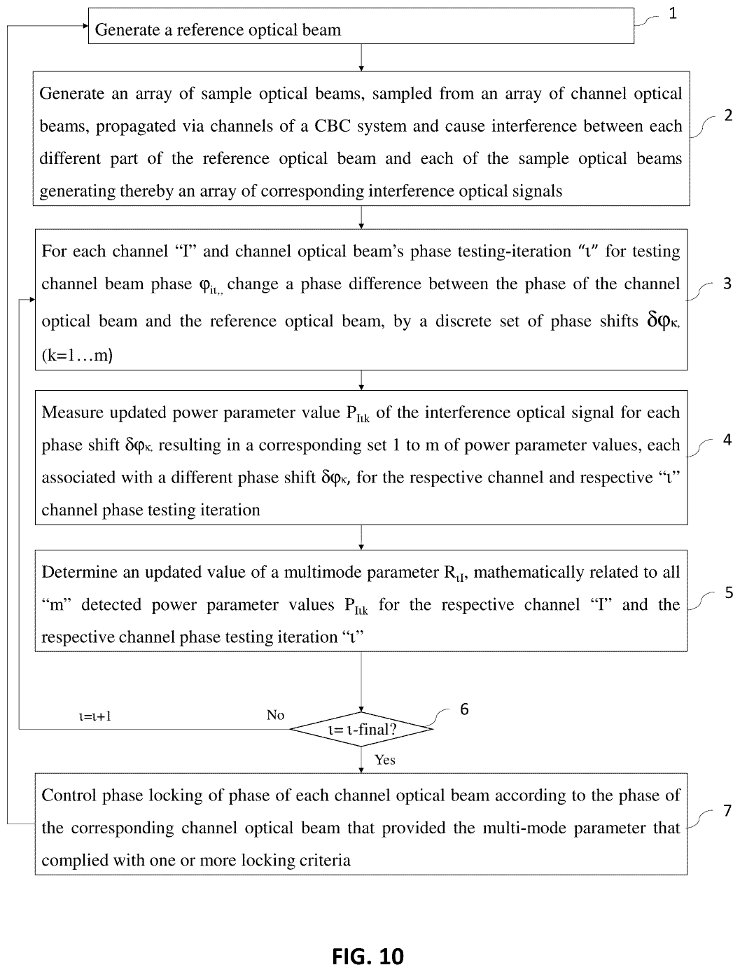

Reference is now made to FIG. 10 showing a flowchart, which schematically illustrate a process/method for phase locking phases of channel optical beam for a CBC system, where the phase-locking is based on phase shifting a phase difference between each of the channel optical beams and a reference optical beam or part(s) thereof, according to some embodiments.

The process may include at least some of the following steps:
(a) generating a reference optical beam 1;
(b) generating an array of sample optical beams, sampled from an array of channel optical beams, propagated via channels of the respective CBC system and causing optical interference between each part of the reference optical beam and a corresponding sample optical beam generating thereby an array of corresponding interference optical signals, e.g., by directing each sample optical beam such as to interfere with a different portion of the reference optical beam, using one or more optical devices/elements such as by using a beam splitter 2;
(c) for each channel “I” and channel optical beam's phase testing-iteration “ι” (out of multiple iterations of a testing session), for testing channel beam phase φ_{Iι}:
changing a phase difference Δφ_{Iι} between the phase of the channel/sample optical beam and the reference optical beam, by a discrete set of phase shifts δφₖ, (where k=1 . . . m and “m” is an integer number larger than 1) 3;
measuring updated power parameter value P_{Iik} of the interference optical signal for each phase shift δφₖ, resulting in a corresponding set of 1 to m power parameter values, each associated with a different phase shift δφₖ, for the respective channel “I” and respective “ι” channel phase testing iteration, where the power parameter may be associated with the intensity (such as the overall intensity) of the corresponding interference signal of the corresponding channel “I” and “ι” channel phase testing iteration 4;
determining an updated value of a modes-parameter R_{iI}, mathematically related to all “m” detected power parameter values P_{Iik} for the respective channel “I” and the respective channel phase testing iteration “ι” 5,
where sub-steps of step (c) may be repeated for a number of times, limited by a predetermined iterations timespan 6 or a limited predefined number of iterations; and
(d) controlling phase locking of phase of each channel optical beam according to the phase of the corresponding channel optical beam that provided the value of the modes-parameter (of the corresponding channel) that complied with at least one locking criterion, such as, for example, the minimum modes-parameter value for the corresponding channel and iteration, from all measured/determined corresponding modes-parameter values 7.

According to some embodiments, the changing of the phase difference Δφ_{Iι} between the phase of the channel/sample optical beam and the reference optical beam may be done, for example, by one of:
(i) phase-modulating the reference optical beam by using a phase modulation device configured to modulate the entire reference optical beam, by a discrete sequence of phase shifts δφₖ;
(ii) phase shifting the phase of each channel optical beam and/or its corresponding sample optical beam, using a phase shifter (PS) of the respective channel, by a discrete sequence of phase shifts δφₖ;
(iii) phase shifting each portion of the reference optical beam separately, by a discrete sequence of phase shifts δφₖ, using an array of phase modulators (PMs) located such that each PM receives therethrough and phase-modulates a different portion of the reference optical beam directed to interfere with a corresponding sample optical beam, wherein the sample optical beams are sampled from the output optical beams of the CBC system.

According to some embodiments, the reference beam generation may be done using a referencing unit configured to direct a portion of light from a single light source that is also split to generate coherent input optical beams of the CBC system to be coherently beam combined, e.g. via an optical waveguide such as an optical fiber, such that the reference optical beam is of the same wavelength or wavelength bandwidth of the channel/input optical beams of the CBC system.

The reference optical beam whether modulated or not, may be then directed to interfere with all the sample optical beams of all channels of the CBC system, by one or more optical elements of the referencing unit, such as by using a collimator to flatten phase distribution of the reference optical beam emanating from the optical fiber guiding thereof, such that each portion of the reference optical beam would be able to interfere with each of the sample optical beams.

According to some embodiments, the CBC system may include a CBC unit configured at least to coherently beam combine an array of input optical beams emanating from the light source(s) of the CBC system's illumination unit. These input optical beams, which may be referred to, in some embodiments, as the channel optical beams, are combined by the CBC unit, which outputs a corresponding array of output optical beams propagated in parallel propagation direction, in respect to one another, defining thereby an optical axis parallel to this propagation direction, forming thereby the outputted combined optical beam.

According to some embodiments, the input optical beam may be also directed such that they are parallel to one another and optionally also to the optical axis, at least when entering the CBC unit.

According to some embodiments, the phase difference being shifted may be the phase difference between each input optical beam, before being beam combined by the CBC unit.

According to some embodiments, the sample optical beams may be samples of the input optical beams.

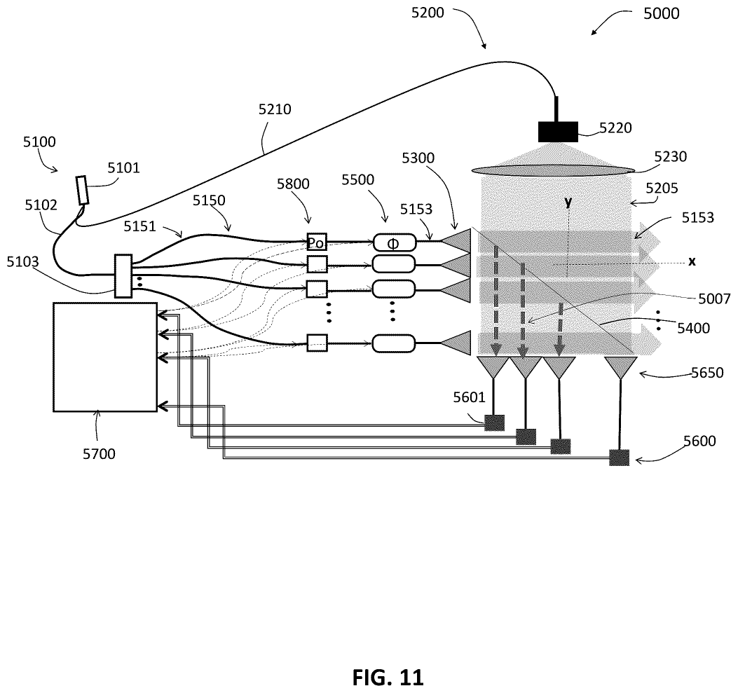

Reference is now made to FIG. 11, schematically illustrating a CBC system 5000, including a phase-locking subsystem that is based on reference optical beam phase-modulation, according to some embodiments. The CBC system 5000 may include, for example:
an illumination unit 5100 including one or more light sources such as coherent light source 5101 and one or more beam dividers/splitters such as beam divider 5103 for generating a plurality of input optical beams 5151 forming part of the plurality of the channel optical beam directed through the CBC system 5000;
a CBC unit including, for example, an array of collimators such as collimation array 5300, for beam combining the input optical beams 5151 such as to output a corresponding array of (collimated) output optical beams 5153 propagated at a substantially parallel propagation direction, in respect to one another, forming thereby the combined optical beam for increased far field (FF) CBC performances;
a phase locking subsystem including at least:
(i) an array of phase shifters (PSs) 5500 each PS being configured to shift phase φ_{Iι} of a different input optical beam 5151 of its corresponding channel “I”;
(ii) a referencing unit 5200 including for example:
an optical waveguide such as a referencing fiber 5210, configured to direct light from the light source 5101 to generate a reference optical beam from the light source 5101;
a phase-modulation device 5220 optionally connectable to the referencing fiber 5210, where the phase-modulation device 5220 may be configured to phase-modulate the reference optical beam outputted from the referencing fiber 5210 according to a repeatable discrete phase-modulation sequence of an “m” number of different shifting-modes, where “m” is an integer number, which may be higher than 1;
(optionally) one or more optical elements and/or devices such as a collimator 5230, configured to direct the modulated reference optical beam 5205 towards a desired direction and optionally also for spatially expanding or collimating the modulated reference optical beam 5205;
(iii) a sampling unit configured to sample a portion of each of the output optical beams 5153 and direct each sample optical beam at a propagation direction that enables it to interfere with a portion of the modulated reference optical beam 5205 (e.g., in parallel to the propagation direction of the modulated reference optical beam 5205) such as to form a corresponding interference optical signal thereby forming an array of interference optical signals 5007, the sampling unit may include for example a beam splitter (BS) 5400, for directing portions of the output optical beams 5153 to interfere with the modulated reference optical beam 5205 and other portions of the output optical beams 5153 to be outputted as the output combined optical beam of the CBC system;
(iv) a detection unit including at least an array of optical detectors such as detectors array 5600, each optical detector 5601 may be positioned and configured to detect/measure intensity of a different interference optical signal 5007 of a different channel, and output a corresponding power parameter value P_{Iιk} of the respective channel “I”, proportional/related to the overall intensity of the detected interference optical signal;
(v) a processing and control unit 5700 configured at least to:
control changing of the phase of each channel optical beam to an updated phase [symbol] ;
for each channel “I” and each phase φ_{Iι} of the corresponding channel optical beam:
(a) receive an updated value P_{Iιk} of the power parameter of the respective shifting-mode “k”, from the optical detector of the corresponding channel “I” and corresponding channel optical beam phase φ_{Iι}, for each of the shifting-modes k=1 . . . m; and
(b) determine an updated value of a modes-parameter R_{ιI}, the modes-parameter R_{ιI}, representing mathematical relation between detected values P_{Iιk} of the power parameter of all shifting-modes k=1 to m of the respective channel for the specific channel optical beam phase φ_{Iι};
determine whether the value of the modes-parameter R_{ιI} complies with at least one predefined locking criterion, and, upon compliance with the at least one locking criterion, temporarily lock the phase of the respective channel optical beam of the respective channel “I” to the phase φ_{Iι}.

According to the above phase-locking method, which is based on value the modes-parameter R_{ιI} for each phase φ_{Iι} being set for each channel optical beam of each channel “I”, the phase of each channel optical beam can be locked to the phase q that is associated with the modes-parameter R_{ιI} that met the at least one locking criterion. Since the value of the modes-parameter Ru is associated with the intensity (power) related values of the interference optical signals of the same channel optical beam, set at the same updated phase φ_{Iι}, for all shifting-modes k=1 to m of the reference optical beam 5205. This phase locking methodic using overall intensity related power parameter values outputted from each optical detector 5601, may improve CBC reliability and accuracy, using overall intensity output of the corresponding optical detector 5601, without requiring a more time-consuming searching for a more specific pattern of the behavior of the detector's output power or energy spatial distribution of the interference optical signal over the optical detector's 5601 effective detection surface.

According to some embodiments, the detectors array 5600 may include an array of photodiode optical detectors 5601.

According to some embodiments, the input optical beams 5151 may be directed to the array of PSs 5300 by using an array of optical fibers 5150.

According to some embodiments, the phase shifting/changing, of the channel optical beam, from an initial phase to all other different phases until being locked to the determined locking phase, may be time-limited to a predefined and optionally adjustable testing timeframe ΔTₜ, which may be limited to be smaller than or equal to an estimated natural phase changing timeframe ΔT_{nc} at which phase of channel optical beams and/or source beam is naturally changed due to source and/or other CBC system components and/or functionality limitations. The testing timeframe ΔTₜ may be a summation of all phase changes and processing time required before the channel optical beam's phase is locked. Therefore, ΔTₜ may be defined as a “locking feedback cycle timeframe”.

A channel optical beam's phase shifting timeframe ΔTₚₛ, for each different phase of a channel optical beam within the testing timeframe ΔTₜ of the locking feedback cycle may also be defined and set such as to be larger than or equal to a modulation sequence (modes) timeframe Δtₘ, which may be defined as the modulation sequence timing or timespan, i.e., the timespan for completion of a single sequence of the reference optical beam's modulation sequence, for all shifting-modes 1 to m, while the channel optical beam is maintained at the same phase.

According to some embodiments, the number of shifting-modes should be limited to enable the modulation sequence timeframe Δtₘ, processing and decision-making timing and locking timing to all fit into the phase shifting timeframe ΔTₘ, while ensuring enough time for making several (at least two) phase changes of the channel optical beam's phase, also limited by the testing timeframe ΔTₜ, which is limited by the estimated natural phase changing timeframe ΔT_{nc}, such that ΔTₜ is equal to or smaller than ΔT_{nc} such that: ΔTₜ≤ΔT_{nc}.

According to other embodiments, the CBC system and phase-locking subsystem may be designed similarly to the design of FIG. 5A, such that the phase-locking subsystem also includes an array of phase modulators (PMs) such as an array of SLMs, each configured to separately phase-modulate a different segment/portion of the reference optical beam before interfering with each output optical beam, outputted from the CBC unit (collimation array). In this case, the processing and control unit may be configured to control each of the PMs separately also for non or zero angle beam steering of the combined optical beam, outputted from the CBC unit.

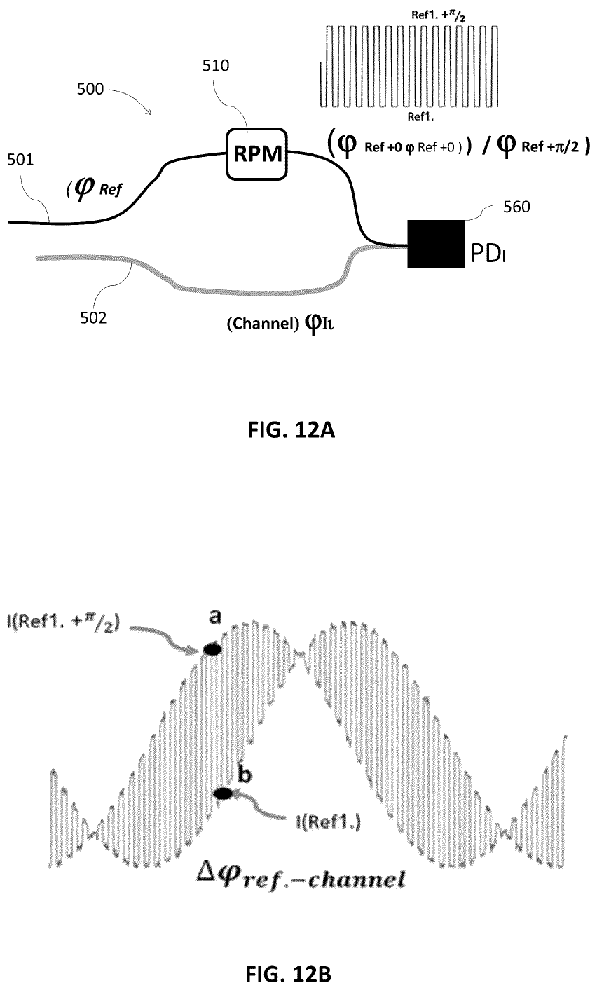

FIGS. 12A and 12B illustrate how the phase locking can be implemented for one of the CBC system's channels' feedback loop arrangement 500, when using a binary discrete (two shifting-modes) phase shifting of the reference optical beam, according to some embodiments.

According to this example, the reference optical beam is sequentially modulated by a phase-modulation device by a sequence of two shifting-modes k=1 and k=2, where in the first shifting-mode the phase of the reference optical beam is not shifted i.e., δφ₁=0 and in the second shifting-mode the phase of the reference optical beam shifted by δφ₂=π/2.

A reference optical beam 501 is directed through a phase-modulator 510 which alternately modulates it by phase shifting it by a phase shift of 0 and of π/2. The modulated reference optical beam 501 is interfered with a channel optical beam 502 (e.g., an output optical beam of the respective channel which is outputted from a corresponding collimator) forming a corresponding interference beam. A corresponding optical detector 560 (such as a photodiode) detects the overall intensity of the interference optical signal at each given moment and outputs, at each given timeframe/time a corresponding power parameter value indicative of (e.g., linear proportional to) the current/updated overall intensity of the interference optical signal.

FIG. 12B shows a simulated phase difference Δφ behavior over time, between a phase of the channel optical beam φ_{channel} and the phase of the reference optical beam φ_{ref}, for the feedback loop arrangement 500 of FIG. 12A, using the binary discrete phase modulation of 0 and π/2 phase shifting of the reference optical beam. The intensities of the corresponding interference optical signal are measured (by the optical detector 560) at each given timeframe Δtₘ, such as to receive values of the power parameter and therefore values of the intensity for each shifting-mode of the reference beam: Iₐ and I_{b}, where Iₐ represents the intensity of the interference signal when the phase of the reference beam is not shifted (Δφ_{ref}=δφ₁=0) and I_{b} represents the intensity of the interference signal when the phase of the reference beam is shifted by π/2 (Δφ_{ref}=δφ₂=π/2).

In this case, the modes-parameter's value can be calculated as follows:

R=Δ=\sqrt{(Iₒ₁−Iₐ)²+(Io₂−I_{b})²}

Where I₀ₐ is a predefined constant (desired) intensity value of the interference optical signal fora zero 0 phase shift of the reference optical beam; and I_{0b} is a predefined constant (desired) intensity value of the interference optical signal for π/2 phase shift of the reference optical beam.

The phase locking criteria, for locking the phase φ_{channel} of the channel optical beam 502 of the respective channel, may be reaching a minimum value of the modes-parameter “R” within the limited locking feedback cycle timeframe ΔT_{fc}.

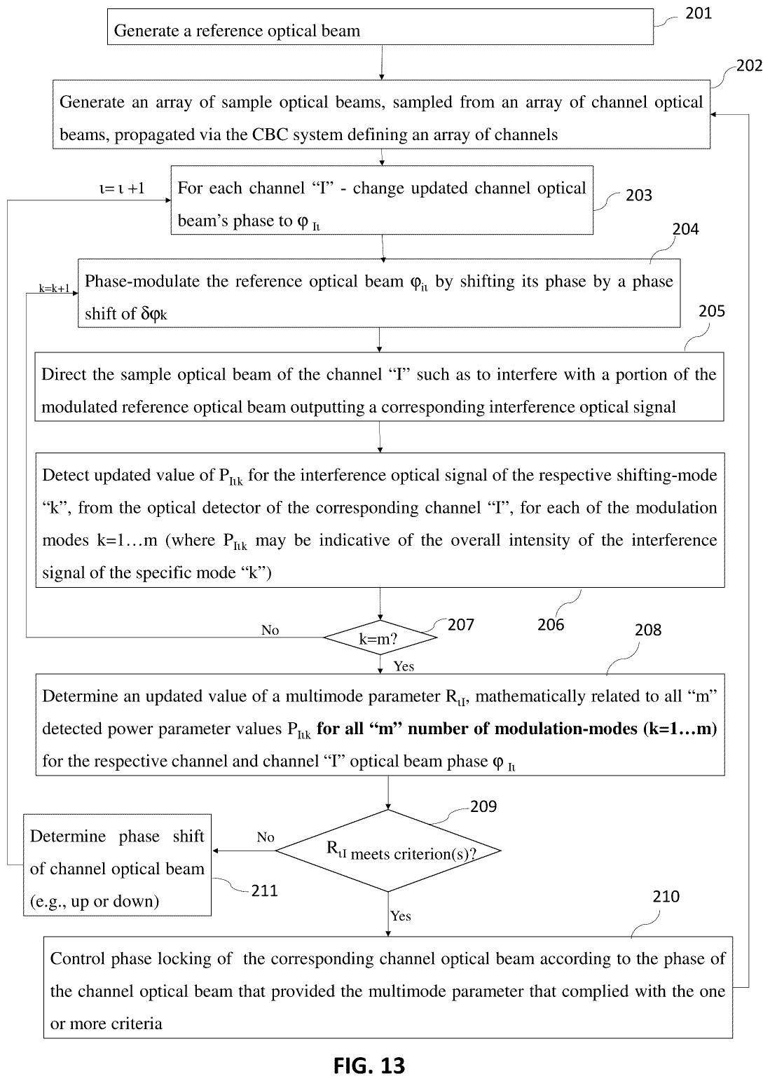

Reference is now made to FIG. 13, schematically illustrating a method for feedback loop based temporal phase locking of a phase of each channel optical beam of channels of a CBC system, based on reference optical beam modulation, according to some embodiments. This method may include the following steps:
generating a reference optical beam (step 201) e.g., of a narrow wavelength bandwidth;
generating an array of sample optical beams, sampled from an array of channel optical beams, propagated via the CBC system defining an array of channels (step 202), for example by splitting an array of output optical beams (which are the channel optical beams of the CBC system, outputted from a CBC unit configured to beam-combine an array of corresponding input optical beams, which are the channel optical beams of the CBC system before being beam-combined);
for each channel “I”—changing the updated (current) channel optical beam's phase e.g., by increasing or decreasing the channel phase by a phase shift of Δφ (step 203), and maintaining this updated phase: φ_{Iι}=φ_{Iι-1}+Δφ, for/during a testing timeframe of ΔTₜ;
within that timeframe ΔTₜ, for the respective channel “I” and channel optical beam phase φ_{Iι}:
phase-modulating the reference optical beam φ_{Iι} to the next shifting-mode “k” e.g., by shifting its phase by a phase shift of δφₖ based on a “k” shifting mode from a modulation sequence of a “m” number of predetermined shifting-modes such that k is an index number from 1 to m and m is larger than 1 (step 204);
directing the sample optical beam such as to interfere with a portion of the modulated reference optical beam outputting a corresponding interference optical signal (step 205);
for each of the “m” shifting-modes of the modulation sequence applied to the reference optical beam for the specific phase φ_{Iι} of the channel optical beam detecting updated value of P_{Iιk} for the interference optical signal of the respective shifting-mode “k”, from the optical detector of the corresponding channel “I”, for each of the shifting-modes k=1 . . . m (where P_{Iik} may be indicative of the overall intensity of the interference signal of the specific mode “k”) (step 206);
once power parameter values of all shifting-modes for the specific channel optical beam phase φ_{Iι} are detected/acquired (Step 207): determining an updated value of a modes-parameter R_{ιI}, mathematically related to all “m” detected power parameter values P_{Iιk} for all “m” number of shifting-modes (k=1 . . . m) for the respective channel “I” and the respective channel optical beam phase φ_{Ii} (step 208); and
when the value of the currently measured modes-parameter R_{ιI} meets one or more predefined criteria (step 209), controlling phase locking of the corresponding channel optical beam according to the phase of the channel optical beam that provided the modes-parameter that complied with the one or more criteria (step 210).

The phase locking may be controlled, for example, by applying the value of the phase φ_{Iι} of the corresponding channel optical beam determined as the “locking phase” to a corresponding phase shifter device controlling phase of the respective channel optical beam, e.g., by controlling voltage/power supplied to the corresponding phase shifter.

According to some embodiments, as shown in FIG. 13, if the value of the currently measured modes-parameter R_{ιI} has not yet met the one or more locking criteria, a decision-making process/step may be performed (step 211), for determining the phase-shift required for the channel optical beam (e.g., whether an increase or decrease of the phase φ_{Iι}by a phase shift δφ is required, based on modes-parameter values previously/recently measured for previous channel optical beam phase changes.

For example, if the locking criterion may be a minimal modes-parameter value, out of one or more (e.g., two) sequential last determined modes-parameter values R_{ιI} and R_{ι-1I} for corresponding one or more sequential last channel optical beam phases φ_{Iι} and φ_{Iι-1}, for a reduction of the channel optical beam phase, that show a reduction in the modes-parameter value R_{ιI}, the next phase change of the phase φ_{Iι+1} may be determined to include reducing the phase of the channel optical beam by the phase shift of δφ. In this case, the feedback loop for locking the phase of the channel optical beam may be terminated when a testing timeframe ΔTₜ is reached and/or when the next value of the modes-parameter shows an increase in respect to the previous modes-parameter value (in which case the phase of the channel optical beam is locked to the previous phase of φ_{Iι-1}).

In some embodiments, within each given feedback cycle timeframe ΔT_{fc}, for a specific channel “I”, the modes-parameter values of several phases of the channel optical beam are checked, where a locking phase φ_{IL} may be selected as one of the checked phases of the channel optical beam, that yielded an extremum value such as the lowest modes-parameter value, where the channel optical beam phase is locked to the selected locking phase φ_{IL}.

### EXAMPLES

Example 1 is method for coherent beam combining (CBC) comprising:
generating a source optical beam, using a light source;
dividing the source optical beam into an array of temporally coherent input optical beams and a reference optical beam;
generating an array of output optical beams corresponding to the array of input optical beams such that the output optical beams propagate along a first propagation direction;
dividing each of the output optical beams such that a first portion of each of the output optical beams is directed towards the first propagation direction, all first portions of the output optical beams forming a combined output optical beam, and a second portion of each of the output optical beams is directed towards a second propagation direction and used as a sample optical beam;
directing the reference optical beam, such that the reference optical beam interferes with the sample optical beams, generating a plurality of corresponding optical interference signals;
providing a plurality of optical detectors, each being positioned and configured to measure an overall intensity of a different optical interference signal, and generate a power output value, indicative of the detected overall intensity of its respective optical interference signal;
automatically and separately changing a phase of each of the input optical beams, while comparing the measured power output value of its corresponding optical interference signal with at least one previously measured power output value generated by the respective optical detector, wherein the changing of the phase of each input optical beam is carried out directly based on the measured power output values of its respective optical interference signals, without calculating or estimating the correct phase and/or without producing any other signal associated therewith; and
locking the phase of the input optical beam when reaching an extremum power output value of its respective optical interference signal,
wherein the generating of the optical interference optical signals, measuring of the power output values of the multiple optical detectors and phase locking are carried out continuously and simultaneously for all input and output optical beams and optical interference signals.

In example 2, the subject matter of example 1 may include, wherein the changing of the phase of each input optical beam is carried by using an array of phase shifters (PSs), each PS being configured to change the phase of a respective input optical beam, and M×N control modules (CMs), each CM being associated with a different PS and a corresponding optical detector and configured to iteratively transmit control commands to its associated PS, based on the power output value received from the respective optical detector.

In example 3, the subject matter of example 2 may include, wherein the control command for each input PS are indicative only of an increase or decrease direction of the respective phase, such that each PS increases or decreases the phase of the respective input optical beam by predefined and/or controllable phase shift span Δϕ.

In example 4, the subject matter of any one or more of examples 1 to 3 may include, wherein the step of generating the output optical beams is carried out using an array of collimating elements for separately collimating each of the input optical beams.

In example 5, the subject matter of any one or more of examples 1 to 4 may include, wherein the method may further comprise controlling one or more characteristics of a wave-front of the combined output optical beam.

In example 6, the subject matter of example 5 includes, wherein the one or more characteristics the wave-front of the combined output optical beam comprises one or more of:
far field (FF) distribution of the wave-front;
FF position of a central lobe formable by the combined output optical beams;
central lobe focusing characteristics;
wave-front spatial configuration;
environmental optical aberrations corrections.

In example 7, the subject matter of any one or more of examples 5 to 6 may include, wherein the controlling of the one or more wave-front characteristics is carried out by controlling direction of a wave-front of the reference optical beam.

In example 8, the subject matter of example 7 may include, wherein the controlling of the wave-front of the reference optical beam is carried out by:
mechanically moving of an output end of an optical waveguide from which the reference optical beam is outputted; and/or
mechanically changing a relative positioning between the optical waveguide output end and a focusing lens located within the pathway of the reference optical beam.

In example 9, the subject matter of any one or more of examples 5 to 6 may include, wherein the controlling of the one or more wave-front characteristics is carried out by using an array of phase controlling modules (PCMs), each PCM positioned and configured to control the phase of a different portion of the reference optical beam interfering with a respective sample optical beam.

In example 10, the subject matter of example 9 may include, wherein the array of PCMs are electronically and/or digitally controllable.

In example 11, the subject matter of example 10 may include, wherein the array of PCMs comprise an array of spatial light modulators.

In example 12, the subject matter of any one or more of examples 5 to 11 may include, wherein the controlling of the one or more characteristics of the wave-front of the combined output optical beam is done according to a FF position of a target.

In example 13, the subject matter of any one or more of examples 1 to 12, wherein the method may further include controlling polarization of each of the input optical beams, based on the received power output value of its respective optical interference signal.

In example 14, the subject matter of example 13 may include, wherein the controlling of the polarization of each of the input optical beams comprises the steps of:
automatically, and separately changing the polarization of each of the input optical beams, while comparing the measured power output value of the respective optical interference signal with at least one previously measured power output value from the respective optical detector; and locking the polarization of each respective input optical beam when reaching an extremum power output value from the respective optical detector, wherein the changing of the polarization of each input optical beam is carried out directly based on the measured power output values of its respective optical interference signals, without calculating or estimating the correct polarization and/or without producing any other signal associated therewith.

In example 15, the subject matter of any one or more of examples 1 to 14, wherein the method may further include a controllably focusing of the combined output optical beam, using a controllable output beam collimating device.

Example 16 is a system for coherent beam combining (CBC) comprising:
a light source, generating a source optical beam;
a beam splitting mechanism, configured to divide the source optical beam into an array of temporally coherent input optical beams and a reference optical beam;
an array of collimating elements, configured to direct each of the input optical beams through a separate collimating element, generating output optical beams corresponding to the input optical beams passed through the collimating elements, such that the output optical beams are parallel to one another, defining a first propagation direction;
a beam splitting element, configured to divide each of the output optical beams such that a first portion of each of the output optical beams is directed towards the first propagation direction, all first portions of the output optical beams forming a combined output optical beam and a second portion of each of the output optical beams is directed towards a second propagation direction and used as a sample optical beam;
an array of optical detectors, each being positioned and configured to measure an overall intensity of a respective optical interference signal and output a power output value that corresponds to the overall intensity of the respective optical interference signal;
a control subsystem, configured to continuously receive measured power output values from each of the optical detectors, change a phase of each of the input optical beams, while comparing the measured power output value of the respective optical interference signal with at least one previously measured power output value from the respective optical detector, and lock the phase of the input optical beam when reaching an extremum power output value of its respective optical interference signal,
wherein the changing of the phase of each input optical beam is carried out directly based on the measured power output values of its respective optical interference signals, without calculating or estimating the correct phase and/or without producing any other signal associated therewith,
wherein the generating of the optical interference optical signals, measuring of the outputs of the multiple optical detectors and phase locking are carried out continuously and simultaneously for all input and output optical beams and optical interference signals.

In example 17, the subject matter of example 16 may include, wherein the control subsystem comprises one or more of:
phase shifters (PSs), each PS being configured to change the phase of a different input optical beam; and
processing modules (PMs), each PM being configured to receive power output value of a different optical detector and control a PS associated therewith, in an iterative manner.

In example 18, the subject matter of any one or more of examples 16 to 17, wherein the system may further include one or more of:
a reference optical fiber for guiding the reference beam, the optical fiber having an input end for inputting light from the light source and an output end from which the reference beam is emitted; and
a reference beam collimator positioned such as to collimate the reference optical beam before interfering with the sample optical beams.

In example 19, the subject matter of any one or more of examples 16 to 18, wherein the system further includes a wave-front control mechanism, configured to control one or more characteristics of a wave-front of the combined output optical beam.

In example 20, the subject matter of example 19 may include, wherein the one or more characteristics of the wave-front of the combined output optical beam comprises one or more of:
far field (FF) distribution of the wave-front;
FF position of a central lobe formable by the combined output optical beams;
central lobe focusing characteristics;
wave-front spatial configuration;
environmental optical aberrations corrections.

In example 21, the subject matter of any one or more of examples 19 to 20 may include, wherein the wave-front control mechanism is configured to control a relative positioning between the reference optical fiber output end and the reference beam collimator, for steering control of the combined output optical beam.

In example 22, the subject matter of any one or more of examples 19 to 20, wherein the system further includes an array of phase controlling modules (PCMs), each PCM positioned and configured to control the phase of a different portion of the reference optical beam interfering with a respective sample optical beam.

In example 23, the subject matter of example 22 may include, wherein the array of PCMs are electronically and/or digitally controllable by the control subsystem or by a separate controller.

In example 24, the subject matter of example 23 may include, wherein the array of PCMs comprise an array of spatial light modulators (SLMs).

In example 25, the subject matter of any one or more of examples 19 to 24 may include, wherein the controlling of the one or more characteristics of the wave-front of the combined output optical beam is done according to a FF position of a target.

In example 26, the subject matter of any one or more of examples 16 to 25, wherein the system may further include polarization controllers (PCs) each PC being associated with a different PM and configured to control polarization of each of the input optical beams, based on the received power output value of its respective measured power output value.

In example 27, the subject matter of example 26 may include, wherein the controlling of the polarization of each of the input optical beams comprises:
automatically, and separately changing the polarization of each of the input optical beams, while comparing the measured power output value of the respective optical interference signal with at least one previously measured power output value of the respective optical interference signal; and
locking the polarization of each respective input optical beam when reaching an extremum power output value of its respective optical interference signal,
wherein the changing of the polarization of each input optical beam is carried out directly based on the measured power output values of its respective optical interference signals, without calculating or estimating the correct polarization and/or without producing any other signal associated therewith.

In example 28, the subject matter of any one or more of examples 16 to 27, wherein the system may further include a focusing device, configured and position to controllably focus the combined output optical beam.

In example 29, the subject matter of any one or more of examples 16 to 28, wherein the system may further include an array of optical waveguides, each being configured to guide therethrough a different input optical beam and/or an output optical beam.

In example 30, the subject matter of example 29 may include, wherein the optical waveguides are: optical fibers, fiber amplifiers, doped fibers.

Example 31 is a method for coherent beam combining (CBC) comprising:
providing an array of temporally coherent input optical beams;
providing a reference optical beam;
generating output optical beams corresponding to the input optical beams such that the output optical beams propagate along a first propagation direction;
dividing each of the output optical beams such that a first portion of each of the output optical beams is directed towards the first propagation direction, all first portions of the output optical beams forming a combined output optical beam and a second portion of each of the output optical beams is directed towards a second propagation direction and used as a sample optical beam;
directing the reference optical beam, such that the reference optical beam interferes with the sample optical beams, generating a plurality of optical interference signals;
providing a plurality of M×N optical detectors, each being positioned and configured to measure an overall intensity respective of each optical interference signal of the plurality of optical interference signals to generate a power output value that corresponds to the overall intensity of the respective optical interference signal;
automatically and separately changing a phase of each of the input optical beams, while comparing the measured power output value of the respective optical interference signal with at least one previously measured power output value generated by the respective optical detector; wherein the changing of the phase of each input optical beam is carried out directly based on the measured power output value of its respective optical interference signal; and
locking the phase of the input optical beam when reaching an extremum power output value of its respective optical interference signal,
wherein the generating of the optical interference optical signals, measuring of the outputs of the multiple optical detectors and phase locking are carried out continuously and simultaneously for all M×N input and output optical beams and optical interference signals.

Example 32 is a system for coherent beam combining (CBC) comprising:
an array of M×N temporally coherent input optical beams;
a reference optical beam;
an array of M×N collimating elements, configured to direct each of the input optical beams through a separate collimating element, generating M×N output optical beams corresponding to the input optical beams passed through the collimating elements, such that the output optical beams are parallel to one another, defining a first propagation direction;
a beam splitting element, configured to divide each of the output optical beams such that a first portion of each of the output optical beams is directed towards the first propagation direction, all first portions of the output optical beams forming a combined output optical beam and a second portion of each of the output optical beams is directed towards a second propagation direction and used as a sample optical beam, directed such as to interfere with the reference optical beam, generating a plurality of optical interference signals;
a plurality of optical detectors, each being positioned and configured to measure an overall intensity of a respective optical interference signal and output a power output value that corresponds to the overall intensity of the respective optical interference signal; and
a control subsystem, configured to continuously receive measured power output values from each of the optical detectors, change a phase of each of the input optical beams, while comparing the measured power output value of the respective optical interference signal with at least one previously measured power output value from the respective optical detector, and lock the phase of the input optical beam when reaching an extremum power output value of its respective optical interference signal,
wherein the changing of the phase of each input optical beam is carried out directly based on the measured power output value of its respective optical interference signal,
wherein the generating of the optical interference optical signals, measuring of the outputs of the multiple optical detectors and phase locking are carried out continuously and simultaneously for all input and output optical beams and optical interference signals.

While the invention has been described with respect to a limited number of embodiments, these should not be construed as limitations on the scope of the invention, but rather as exemplifications of some of the embodiments.

Any digital computer system, unit, device, module and/or engine exemplified herein can be configured or otherwise programmed to implement a method disclosed herein, and to the extent that the system, module and/or engine is configured to implement such a method, it is within the scope and spirit of the disclosure. Once the system, module and/or engine are programmed to perform particular functions pursuant to computer readable and executable instructions from program software that implements a method disclosed herein, it in effect becomes a special purpose computer particular to embodiments of the method disclosed herein. The methods and/or processes disclosed herein may be implemented as a computer program product that may be tangibly embodied in an information carrier including, for example, in a non-transitory tangible computer-readable and/or non-transitory tangible machine-readable storage device. The computer program product may directly loadable into an internal memory of a digital computer, comprising software code portions for performing the methods and/or processes as disclosed herein.

Additionally or alternatively, the methods and/or processes disclosed herein may be implemented as a computer program that may be intangibly embodied by a computer readable signal medium. A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a non-transitory computer or machine-readable storage device and that can communicate, propagate, or transport a program for use by or in connection with apparatuses, systems, platforms, methods, operations and/or processes discussed herein.

The terms “non-transitory computer-readable storage device” and “non-transitory machine-readable storage device” encompasses distribution media, intermediate storage media, execution memory of a computer, and any other medium or device capable of storing for later reading by a computer program implementing embodiments of a method disclosed herein. A computer program product can be deployed to be executed on one computer or on multiple computers at one site or distributed across multiple sites and interconnected by one or more communication networks.

These computer readable and executable instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable and executable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable and executable instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

A module, a device, a mechanism, a unit and or a subsystem may each comprise a machine or machines executable instructions (e.g., commands). A module may be embodied by a circuit or a controller programmed to cause the system to implement the method, process and/or operation as disclosed herein. For example, a module may be implemented as a hardware circuit comprising, e.g., custom very large-scale integration (VLSI) circuits or gate arrays, an application-specific integrated circuit (ASIC), off-the-shelf semiconductors such as logic chips, transistors, and/or other discrete components. A module may also be implemented in programmable hardware devices such as field programmable gate arrays, programmable array logic, programmable logic devices and/or the like.

In the discussion, unless otherwise stated, adjectives such as “substantially” and “about” that modify a condition or relationship characteristic of a feature or features of an embodiment of the invention, are to be understood to mean that the condition or characteristic is defined to within tolerances that are acceptable for operation of the embodiment for an application for which it is intended.

Unless otherwise specified, the terms “substantially”, “′about” and/or “close” with respect to a magnitude or a numerical value may imply to be within an inclusive range of −10% to +10% of the respective magnitude or value.

It is important to note that the method may include is not limited to those diagrams or to the corresponding descriptions. For example, the method may include additional or even fewer processes or operations in comparison to what is described in the figures. In addition, embodiments of the method are not necessarily limited to the chronological order as illustrated and described herein.

Discussions herein utilizing terms such as, for example, “processing”, “computing”, “calculating”, “determining”, “establishing”, “analyzing”, “checking”, “estimating”, “deriving”, “selecting”, “inferring” or the like, may refer to operation(s) and/or process(es) of a computer, a computing platform, a computing system, or other electronic computing device, that manipulate and/or transform data represented as physical (e.g., electronic) quantities within the computer's registers and/or memories into other data similarly represented as physical quantities within the computer's registers and/or memories or other information storage medium that may store instructions to perform operations and/or processes. The term determining may, where applicable, also refer to “heuristically determining”.

It should be noted that where an embodiment refers to a condition of “above a threshold”, this should not be construed as excluding an embodiment referring to a condition of “equal or above a threshold”. Analogously, where an embodiment refers to a condition “below a threshold”, this should not be construed as excluding an embodiment referring to a condition “equal or below a threshold”. It is clear that should a condition be interpreted as being fulfilled if the value of a given parameter is above a threshold, then the same condition is considered as not being fulfilled if the value of the given parameter is equal or below the given threshold. Conversely, should a condition be interpreted as being fulfilled if the value of a given parameter is equal or above a threshold, then the same condition is considered as not being fulfilled if the value of the given parameter is below (and only below) the given threshold.

It should be understood that where the claims or specification refer to “a” or “an” element and/or feature, such reference is not to be construed as there being only one of those elements. Hence, reference to “an element” or “at least one element” for instance may also encompass “one or more elements”.

Terms used in the singular shall also include the plural, except where expressly otherwise stated or where the context otherwise requires.

In the description and claims of the present application, each of the verbs, “comprise” “include” and “have”, and conjugates thereof, are used to indicate that the object or objects of the verb are not necessarily a complete listing of components, elements or parts of the subject or subjects of the verb.

Unless otherwise stated, the use of the expression “and/or” between the last two members of a list of options for selection indicates that a selection of one or more of the listed options is appropriate and may be made. Further, the use of the expression “and/or” may be used interchangeably with the expressions “at least one of the following”, “any one of the following” or “one or more of the following”, followed by a listing of the various options.

It is appreciated that certain features of the invention, which are, for clarity, described in the context of separate embodiments or example, may also be provided in combination in a single embodiment. Conversely, various features of the invention, which are, for brevity, described in the context of a single embodiment, example and/or option, may also be provided separately or in any suitable sub-combination or as suitable in any other described embodiment, example or option of the invention. Certain features described in the context of various embodiments, examples and/or optional implementation are not to be considered essential features of those embodiments, unless the embodiment, example and/or optional implementation is inoperative without those elements.

It is noted that the terms “in some embodiments”, “according to some embodiments”, “according to some embodiments of the invention”, “for example”, “e.g.”, “for instance” and “optionally” may herein be used interchangeably.

The number of elements shown in the Figures should by no means be construed as limiting and is for illustrative purposes only.

It is noted that the terms “operable to” can encompass the meaning of the term “modified or configured to”. In other words, a machine “operable to” perform a task can in some embodiments, embrace a mere capability (e.g., “modified”) to perform the function and, in some other embodiments, a machine that is actually made (e.g., “configured”) to perform the function.

Throughout this application, various embodiments may be presented in and/or relate to a range format. It should be understood that the description in range format is merely for convenience and brevity and should not be construed as an inflexible limitation on the scope of the embodiments. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals there between.

1. A method for locking phases of an array of channel optical beams propagated through channels of a coherent beam combining (CBC) system, the method comprising at least:
(a) generating a reference optical beam;
(b) generating an array of sample optical beams, sampled from the array of channel optical beams, and causing optical interference between each part of the reference optical beam and a corresponding sample optical beam, generating thereby an array of corresponding interference optical signals;
(c) for each channel “I” and channel optical beam's phase testing iteration “ι”, for testing channel beam phase φ_{Iι}:
sequentially changing a phase difference Δφ_{It} between the phase of the channel optical beam or part thereof and the corresponding part of the reference optical beam, by a discrete set of phase shifts δφₖ, where k=1 . . . m, “m” being an integer number larger than 1, defining a discrete sequence of “m” shifting-modes;
measuring updated power parameter value P_{Iιk} of the interference optical signal for each phase shift δφₖ, resulting in a corresponding set 1 to m power parameter values, each associated with a different phase shift δφₖ, for the respective channel “I” and respective “ι” phase testing iteration, where the power parameter is associated with an intensity of the corresponding interference signal of the corresponding channel “I” and phase testing iteration “ι”;
determining an updated value of a modes-parameter R_{ιI}, mathematically related to all “m” detected power parameter values P_{Iιk} for the respective channel “I” and the respective phase testing iteration “ι”; and
(d) controlling phase locking of phase of each channel optical beam according to the phase of the corresponding channel optical beam that is associated with the value of the modes-parameter of the corresponding channel that complies with at least one locking criterion.

2. The method of claim 1, wherein the changing of the phase difference between each channel optical beam and the reference optical beam is carried out by one or more of:
(i) phase-modulating the reference optical beam by using a phase modulation device configured to modulate the entire reference optical beam, according to a discrete sequence of phase shifts δφₖ;
(ii) phase shifting the phase of each channel optical beam and/or its corresponding sample optical beam, using a phase shifter (PS) of the respective channel, by a discrete sequence of phase shifts δφₖ; and/or
(iii) phase shifting each portion of the reference optical beam separately, by a discrete sequence of phase shifts δφₖ, using an array of phase modulators (PMs) located such that each PM receives therethrough and phase-modulates a different portion of the reference optical beam directed to interfere with a corresponding sample optical beam.

3. The method of claim 1, wherein the at least one criterion according to which the phase of each channel optical beam is controllably locked is adjustable based on a currently desired spatial phase distribution of a combined optical beam outputted from the CBC system.

4. The method of claim 3 further comprising controlling desired phase distribution of the combined optical beam by setting a different locking criterion to each channel, for causing intentional specific phase-differences between the channel optical beams, for enabling a desired phased-array beam steering of the combined optical beam.

5. The method of claim 1, wherein the at least one locking criterion comprises at least one of:
an extremum value of the modes-parameter, such that the phase of the channel optical beam is locked to the phase φ_{Iι} that yielded the minimum or maximum modes-parameter R_{ιI} value or an absolute value thereof |R_{ιI}|, between all modes-parameter values determined for all phases of the channel optical beam being tested in each phase locking session; and/or
a minimum value of an absolute distance D between the modes-parameter R_{ιI} and a predefined desired modes-parameter R_{d}: minimum of: D_{ιI}=|R_{d}−R_{ιI}∥, between all modes-parameter values determined for all phases of the channel optical beam being tested in each phase-locking session.

6. The method of claim 1, wherein, for each channel “I”, the overall number of testing iterations in each phase-locking session is limited to a testing timeframe or to a predefined limiting number of testing iterations.

7. The method of claim 6, wherein the phase-locking method steps are performable in an ongoing and/or repeated manner such that phase-locking sessions for each channel are repeatedly performed during operation of the CBC system.

8. The method of claim 1, wherein the overall timeframe for each phase testing iteration is limited to a predefined testing timeframe ΔTₜ that corresponds to an estimated timespan ΔTₑ that is associated with an estimated timespan of a phase shifting sequence Δtₘ for measuring all “m” different phase shifting-modes for shifting the phase difference between the reference optical beam and the corresponding sample optical beam for the particular channel “I”, to enable detecting all power parameter values of all “m” shifting-modes.

9. The method of claim 1, wherein the number of shifting-modes is m=2 such that in a first shifting-mode, k=1, the phase difference between the phase of the reference and channel optical beam is shifted by δφ₁=0 and in a second shifting-mode, k=2, the phase difference is shifted by δφ₂=π/2.

10. The method of claim 9, wherein the modes-parameter R_{ιI} of channel “I” and testing iteration “ι” is mathematically proportional or equal to
(Io₁−I₁)²+(Io₂−I₂)², wherein:
I₀₁ and I₀₂ are predefined constants of desired intensity values of the interference optical signal, respectively, for the first and second shifting-modes: k=1 and k=2;
I₁ is an updated intensity value of the specific channel “I” and specific iteration “ι” for the first shifting-mode k=1, which is proportional to its corresponding power parameter value P_{Iι1}; and
I₂ is an updated intensity value of the specific channel “I” and specific and specific iteration “ι”, for the second shifting-mode k=2, which is proportional to its corresponding power parameter value P_{Iι2}.

11. A phase-locking subsystem, for locking temporary phase of each optical beam of a plurality of channel optical beams propagated through channels of a coherent beam combining (CBC) system,
wherein the phase-locking subsystem is configured to temporarily lock a phase of each channel optical beam, based on:
changing a phase-difference between a reference optical beam and each channel optical beam of each channel “I” of the CBC system, by shifting the phase difference Δφ_{I} by a set of “m” predetermined phase shifts δφₖ, wherein “k” is an integer number from 1 to m and “m” is an integer number larger than 1, defining thereby an “m” number of shifting-modes; and
controlling phase-locking of phase of each channel optical beam according to the phase of the corresponding channel optical beam that is associated with a value of a modes-parameter of the corresponding channel that complied with at least one locking criterion, wherein the modes-parameter value is determined based on values of an intensity related power parameter measured for all shifting-modes.

12. A phase-locking subsystem for locking phases of an array of channel optical beams propagated through channels of a coherent beam combining (CBC) system, the phase-locking subsystem comprising at least:
a referencing unit configured to generate a reference optical beam;
a sampling unit configured to generate an array of sample optical beams, sampled from an array of channel optical beams, propagated via channels of the CBC system and cause optical interference between each part of the reference optical beam and a corresponding sample optical beam, generating thereby an array of corresponding interference optical signals; and
a processing and control unit, configured to control phase-locking of phase of each channel optical beam of each channel at least by performing the following steps for each channel “I” and channel optical beam's phase testing-iteration “ι”, for testing channel beam phase φ_{Iι}:
(i) sequentially changing a phase difference Δφ_{Iι} between the phase of the channel optical beam and the reference optical beam, by a discrete set of phase shifts δφₖ, where k=1 . . . m, “m” being an integer number larger than 1, defining a discrete sequence of “m” shifting-modes;
(ii) measuring updated power parameter value P_{Iιk} of the interference optical signal for each phase shift δφₖ, resulting in a corresponding set of 1 to m power parameter values, each associated with a different phase shift δφₖ, for the respective channel “I” and respective “ι” phase testing iteration, where the power parameter is associated with an intensity of the corresponding interference signal of the corresponding channel “I” and phase testing iteration “ι”; and
(iii) determining an updated value of a modes-parameter R_{ιI}, mathematically related to all “m” detected power parameter values P_{Iιk} for the respective channel “I” and the respective phase testing iteration “ι”; and
(iv) controlling phase-locking of phase of each channel optical beam according to the phase of the corresponding channel optical beam that is associated with the value of the modes-parameter of the corresponding channel that complied with at least one locking criterion.

13. The phase-locking subsystem of claim 12, wherein the changing of the phase difference between each sample optical beam and the reference optical beam is carried out by one or more of:
(i) phase-modulating the reference optical beam by using a phase modulation device configured to modulate the entire reference optical beam, by a discrete sequence of phase shifts δφₖ;
(ii) phase shifting the phase of each channel optical beam and/or its corresponding sample optical beam, using a phase shifter (PS) of the respective channel, by a discrete sequence of phase shifts δφₖ; and/or
(iii) phase shifting each portion of the reference optical beam separately, by a discrete sequence of phase shifts δφₖ, using an array of phase modulators (PMs) located such that each PM receives therethrough and phase-modulates a different portion of the reference optical beam directed to interfere with a corresponding sample optical beam, wherein the sample optical beams are sampled from the output optical beams of the CBC system.

14. The phase-locking subsystem of claim 12, wherein the at least one criterion according to which the phase of each channel optical beam is controllably locked depends on a currently desired phase distribution of a combined optical beam outputted from the CBC system.

15. The phase-locking subsystem of claim 14, wherein the processing and control unit is further configured to control desired phase distribution of the combined optical beam by setting a different locking criterion to each channel, for resulting with intentional specific phase-differences between the reference optical beam and each of the channel optical beam for each channel, such as to enable a desired phased-array beam steering of the combined optical beam.

16. The phase-locking subsystem of claim 12, wherein the at least one locking criterion comprises at least one of:
an extremum value of the modes-parameter, such that the phase of the channel optical beam is locked to the phase φ_{Iι} that yielded the minimum or maximum modes-parameter R_{ιI} value or an absolute value thereof |R_{ιI}|; and/or
a minimum value of an absolute distance between the modes-parameter R_{ιI} and a predefined desired modes-parameter R_{d}: minimum of: |R_{d}−R_{ιI}|.

17. The phase-locking subsystem of claim 12, wherein, for each channel “I”, the overall number of phase testing iterations in each phase-locking session is limited to a testing timeframe or to a predefined limiting number of testing iterations.

18. The phase-locking subsystem of claim 16, wherein the phase-locking steps are performable in an ongoing and/or repeated manner such that phase-locking sessions for each channel are repeatedly performed during operation of the CBC system.

19. The phase-locking subsystem of claim 12, wherein the overall timeframe for each testing iteration is limited to a predefined testing timeframe ΔTt that corresponds to an estimated timespan of a modulation-sequence Δtₘ timeframe for measuring all “m” different phase shifting-modes for shifting difference between the reference optical beam and the corresponding sample optical beam for the particular channel “I”, to enable detecting all power parameter values of all “m” shifting-modes.

20. The phase-locking subsystem of claim 12, wherein the number of shifting-modes is m=2 such that in a first shifting-mode, k=1, the phase difference between the phase of the reference and sample optical beam is shifted by [symbol] =0 and in a second shifting-mode, k=2, the phase difference is shifted by δφ₂=π/2.

21. The phase-locking subsystem of claim 12, wherein the modes-parameter R_{ιI} of channel “I” and testing iteration “ι” is mathematically proportional or equal to
\sqrt{Io₁−I₁²+(Io₂−I₂)²}, wherein:
I₀₁ and I₀₂ are predefined constants of desired intensity values of the interference optical signal, respectively, for the first and second shifting-modes: k=1 and k=2;
I₁ is an updated intensity value of the specific channel “I” and specific iteration “ι” for the first shifting-mode k=1, which is proportional to its corresponding power parameter value P_{Iι1}; and
I₂ is an updated intensity value of the specific channel “I” and specific and specific iteration “ι”, for the second shifting-mode k=2, which is proportional to its corresponding power parameter value P_{Iι2}.

22. The phase-locking subsystem of claim 12, wherein the at least one criterion according to which the phase of each channel optical beam is controllably locked is adjustable based on a currently desired spatial phase distribution of a combined optical beam outputted from the CBC system.
